(19) United States
(12) Patent Application Publication
(10) Pub. No.: US 2026/0033150 A1
(43) Pub. Date: Jan. 29, 2026

(54) DISPLAY DEVICE AND ELECTRONIC DEVICE INCLUDING THE SAME

(71) Applicant: Samsung Display Co., Ltd., Yongin-si (KR)

(72) Inventors: SUNHO KIM, Yongin-si (KR); YOOMIN KO, Yongin-si (KR); JUCHAN PARK, Yongin-si (KR); Yerim Son, Yongin-si (KR); CHUNG SOCK CHOI, Yongin-si (KR)

(21) Appl. No.: 19/261,949

(22) Filed: Jul. 7, 2025

(30) Foreign Application Priority Data
Jul. 26, 2024 (KR) 10-2024-0099198

(51) Int. Cl. H10K 59/122; H10K 59/131

(52) U.S. Cl. CPC H10K 59/122; H10K 59/131

(57) ABSTRACT

A display device includes: a pixel driving circuit including a transistor; a connection electrode electrically connected to the pixel driving circuit; a first electrode arranged on the connection electrode; a pixel defining layer defining an opening exposing a portion of the first electrode; a connection pattern arranged on the connection electrode and the pixel defining layer and electrically connected to the connection electrode; an electrode layer arranged on the first electrode and electrically connected to the connection pattern; a separator arranged on the pixel defining layer and the connection pattern, separating the electrode layer into a plurality of second electrodes spaced apart from each other, and covering at least a portion of the connection pattern; and an additional connection pattern arranged on the pixel defining layer and extending from the connection pattern in a direction away from a central portion of the separator in a cross-section.

### CROSS-REFERENCE TO RELATED APPLICATION

The present application claims priority to and the benefit of Korean Patent Application No. 10-2024-0099198, filed on Jul. 26, 2024, in the Korean Intellectual Property Office, the entire disclosure of which is incorporated herein by reference.

### BACKGROUND

### 1. Field

Aspects of some embodiments of the present disclosure relate generally to a display device and an electronic device including the same.

### 2. Description of the Related Art

With the development of information technology, the importance of a display device, which is a connection medium between a user and information, has been highlighted. For example, the use of display devices such as liquid crystal display (“LCD”) device, organic light emitting diode (“OLED”) display device, plasma display panel (“PDP”) device, quantum dot display device or the like is increasing.

The display device includes a light emitting element and a pixel driving circuit for driving the light emitting element. The light emitting element may be driven by the pixel driving circuit to emit light. To relatively improve the reliability of the display device, research on a connection between the light emitting element and the pixel driving circuit is ongoing.

The above information disclosed in this Background section is only for enhancement of understanding of the background and therefore the information discussed in this Background section does not necessarily constitute prior art.

### SUMMARY

Aspects of some embodiments of the present disclosure relate generally to a display device and an electronic device including the same. For example, aspects of some embodiments of the present disclosure relate to a display device that provides visual information and an electronic device including the display device.

Aspects of some embodiments include a display device with relatively improved display characteristics.

Aspects of some embodiments include an electronic device including the display device.

A display device according to some embodiments of the present disclosure includes: a pixel driving circuit including a transistor; a connection electrode electrically connected to the pixel driving circuit; a first electrode arranged on the connection electrode; a pixel defining layer defining an opening exposing a portion of the first electrode; a connection pattern arranged on the connection electrode and the pixel defining layer and electrically connected to the connection electrode; an electrode layer arranged on the first electrode and electrically connected to the connection pattern; a separator arranged on the pixel defining layer and the connection pattern, separating the electrode layer into a plurality of second electrodes spaced apart from each other, and covering at least a portion of the connection pattern; and an additional connection pattern arranged on the pixel defining layer and extending from the connection pattern in a direction away from a central portion of the separator in a cross-section.

According to some embodiments, a side surface of the separator may contact the connection pattern and may have a plurality of reverse tapered slopes in the cross-section.

According to some embodiments, the plurality of reverse tapered slopes may include a first reverse tapered slope and a second reverse tapered slope. According to some embodiments, the first reverse tapered slope may be connected to an upper surface of the separator, and the second reverse tapered slope may contact the connection pattern.

According to some embodiments, the additional connection pattern may include a same material as the connection pattern.

According to some embodiments, the additional connection pattern may include a transparent conductive oxide.

According to some embodiments, a width of the additional connection pattern may be greater than or equal to 0.3 micrometers and less than or equal to 3 micrometers.

According to some embodiments, a width of the connection pattern may be greater than or equal to 2 micrometers and less than or equal to 4 micrometers.

According to some embodiments, the additional connection pattern and the first electrode may be electrically independent of each other.

According to some embodiments, each of the plurality of second electrodes may be electrically connected to the pixel driving circuit through the connection pattern and the connection electrode.

According to some embodiments, each of the plurality of second electrodes may contact the connection pattern at a position adjacent to or overlapping the separator.

According to some embodiments, the display device may further include an intermediate layer arranged between the first electrode and the electrode layer and including an emission material.

A display device according to some embodiments of the present disclosure includes: a pixel driving circuit including a transistor; a connection electrode electrically connected to the pixel driving circuit; a first electrode arranged on the connection electrode; a pixel defining layer covering a portion of the first electrode and defining an emission area; a connection pattern electrically connected to the connection electrode and surrounding at least a portion of the emission area in a plan view; an electrode layer arranged on the first electrode and electrically connected to the connection pattern; a separator arranged on the pixel defining layer and the connection pattern, separating the electrode layer into a plurality of second electrodes spaced apart from each other, and overlapping the connection pattern in the plan view, and an additional connection pattern extending from the connection pattern and arranged between the connection pattern and the emission area in the plan view.

According to some embodiments, the additional connection pattern may surround at least a portion of the emission area in the plan view.

According to some embodiments, the connection pattern may surround at least a portion of the additional connection pattern in the plan view.

According to some embodiments, the separator may entirely surround the connection pattern and the additional connection pattern in the plan view.

According to some embodiments, a side surface of the separator may contact the connection pattern and has a plurality of reverse tapered slopes in a cross-section.

According to some embodiments, the additional connection pattern may include a same material as the connection pattern.

According to some embodiments, a width of the additional connection pattern may be greater than or equal to 0.3 micrometers and less than or equal to 3 micrometers.

According to some embodiments, the additional connection pattern and the first electrode may be electrically independent of each other.

According to some embodiments, each of the plurality of second electrodes may be electrically connected to the pixel driving circuit through the connection pattern and the connection electrode.

An electronic device according to some embodiments of the present disclosure includes: a display device including a pixel; and a processor which transmits an image data signal and an input control signal to the display device. According to some embodiments, the display device includes: a pixel driving circuit including a transistor; a connection electrode electrically connected to the pixel driving circuit; a first electrode arranged on the connection electrode; a pixel defining layer defining an opening exposing a portion of the first electrode; a connection pattern arranged on the connection electrode and the pixel defining layer and electrically connected to the connection electrode; an electrode layer arranged on the first electrode and electrically connected to the connection pattern; a separator arranged on the pixel defining layer and the connection pattern, separating the electrode layer into a plurality of second electrodes spaced apart from each other, and covering at least a portion of the connection pattern; and an additional connection pattern arranged on the pixel defining layer and extending from the connection pattern in a direction away from a central portion of the separator in a cross-section.

A display device according to some embodiments of the present disclosure may include a connection electrode, a connection pattern, and a separator. Thus, a cathode on an anode may be easily connected to a pixel driving circuit. According to some embodiments, the cathode on the anode may be connected to a drain of a driving transistor of the pixel driving circuit through the connection electrode and the connection pattern. Accordingly, a gate-to-source voltage (Vgs) of the driving transistor may not change even when a light emitting element deteriorates. Accordingly, a range of change in a driving current due to the deterioration of the light emitting element may be relatively reduced. Accordingly, the after-image defect of the display device depending on an increase in the time of use may be relatively reduced, and the lifespan of the display device may be relatively improved.

In addition, a display device according to some embodiments of the present disclosure may further include an additional connection pattern extending from the connection pattern. Accordingly, even if the process distribution occurs in a process of forming the separator, a double reverse tapered structure may be smoothly formed on a side surface of the separator. Accordingly, separation (or disconnection) of an electrode layer by the separator may be more easily implemented.

### BRIEF DESCRIPTION OF THE DRAWINGS

Illustrative, non-limiting embodiments will be more clearly understood from the following detailed description in conjunction with the accompanying drawings.

FIG. 1A is a plan view illustrating a display device according to some embodiments of the present disclosure.

FIG. 1B is a plan view illustrating a display device according to some embodiments of the present disclosure.

FIG. 2A is a circuit diagram illustrating an example of a circuit structure of a pixel included in the display device of FIGS. 1A and 1B.

FIG. 2B is a circuit diagram illustrating another example of a circuit structure of a pixel included in the display device of FIGS. 1A and 1B.

FIG. 2C is a circuit diagram illustrating still another example of a circuit structure of a pixel included in the display device of FIGS. 1A and 1B.

FIG. 3 is a plan view illustrating a portion of an area of the display device of FIGS. 1A and 1B.

FIG. 4 is an enlarged plan view illustrating one unit emission area among the unit emission areas of FIG. 3.

FIG. 5 is a cross-sectional view taken along the line I-I′ of FIG. 4.

FIG. 6 is an enlarged cross-sectional view of the area A of FIG. 5.

FIG. 7 is a block diagram of an electronic device according to some embodiments of the present disclosure.

FIG. 8 is a schematic diagram of an electronic device according to some embodiments.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and some redundant descriptions of the same components may be omitted.

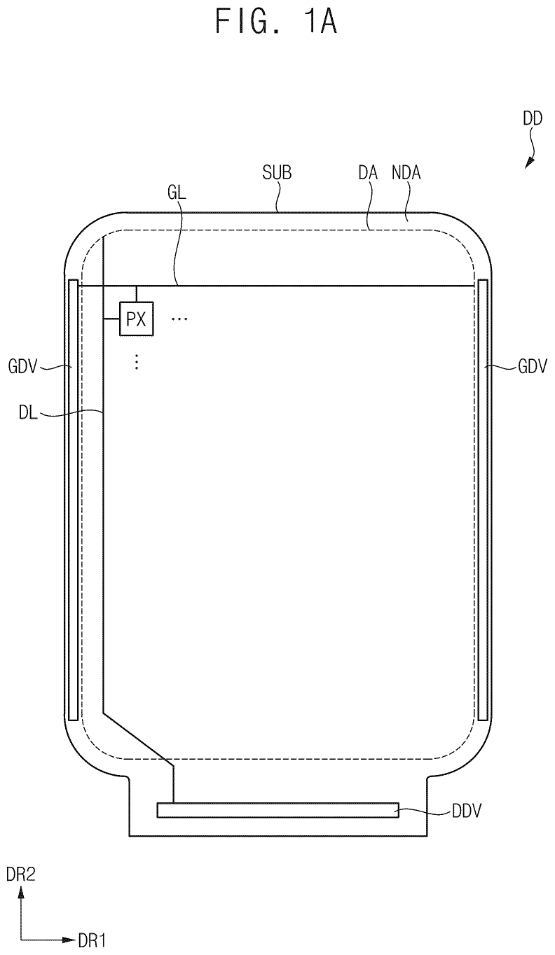

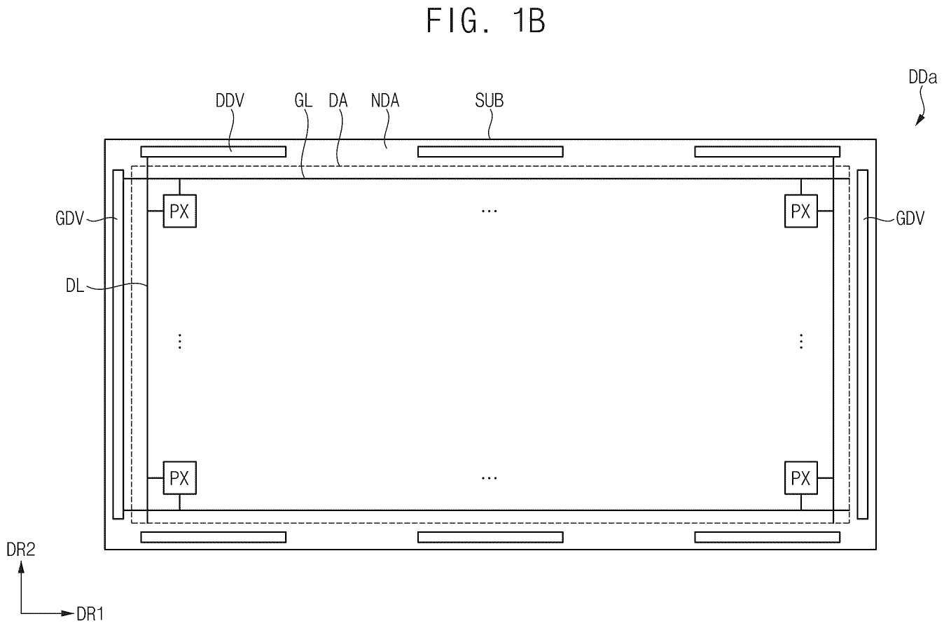

FIG. 1A is a plan view illustrating a display device according to some embodiments of the present disclosure. FIG. 1B is a plan view illustrating a display device according to some embodiments of the present disclosure.

In this specification, a plane may be defined by a first direction DR1 and a second direction DR2 intersecting the first direction DR1. For example, the first direction DR1 and the second direction DR2 may be perpendicular to each other. A display device and various components or layers thereof may have a thickness extended along a third direction which crosses or intersects the plane, that is, each of the first direction DR1 and the second direction DR2 may be perpendicular to the third direction.

Referring to FIGS. 1A and 1B, a display device DD (or DDa) may be a device activated according to an electrical signal. For example, the display device DD may be a small-sized display device used in a small-sized electronic device such as a smart phone, a mobile phone, a smart watch, a game console, a camera, or the like. In addition, the display device DDa may be a medium and large-sized display device used in medium and large-sized electronic devices such as a laptop, a tablet PC, a television, a computer monitor, a vehicle monitor, an external billboard, or the like. FIG. 1A illustrates the display device DD as an example of the small-sized display device, and FIG. 1B illustrates the display device DDa as an example of the medium and large-sized display device.

The display device DD (or DDa) may include a display area DA and a peripheral area NDA. The display area DA may be an area that displays images by generating light or controlling a transmittance of light provided from an external light source. The peripheral area NDA may be located around (e.g., in a periphery or outside a footprint of) the display area DA. For example, the peripheral area NDA may surround at least a portion of the display area DA. According to some embodiments, the peripheral area NDA may be an area that does not display images. However, embodiments according to the present disclosure are not limited thereto, and images may be displayed in at least a portion of the peripheral area NDA. For example, a light emitting element that emits light may be located in at least a portion of the peripheral area NDA.

The display device DD (or DDa) may include a substrate SUB, pixels PX, gate lines GL, data lines DL, a data driver DDV, and a gate driver GDV.

The substrate SUB may serve as a base of the display device DD (or DDa). According to some embodiments, examples of materials that may be used as the substrate SUB may include glass, quartz, silicon, polymers, or the like. These may be used alone or in combination with each other. In addition, the substrate SUB may have a single-layer structure or a multi-layer structure in which a plurality of layers including different materials are stacked.

The pixels PX may be located in the display area DA on the substrate SUB. The pixels PX may be electrically connected to the gate lines GL and the data lines DL. For example, the pixels PX may be arranged in a matrix form or arrangement in the first direction DR1 and the second direction DR2. Each of the pixels PX may include a pixel driving circuit and a light emitting element. The light emitting element may emit light. The light emitting element may be an organic light emitting diode or an inorganic light emitting diode.

Each of the gate lines GL and each of the data lines DL may cross each other. For example, each of the gate lines GL may generally extend in the first direction DR1, and the gate lines GL may be arranged in the second direction DR2. Each of the data lines DL may generally extend in the second direction DR2, and the data lines DL may be arranged in the first direction DR1. However, embodiments according to the present disclosure are not limited thereto.

The data driver DDV may be located in the peripheral area NDA on the substrate SUB. The data driver DDV may generate a data voltage. The data driver DDV may output the data voltage to the data lines DL. The data voltage may be applied to the pixels PX through the data lines DL.

According to some embodiments, the data driver DDV may be mounted on the substrate SUB. However, embodiments according to the present disclosure are not limited thereto, and the data driver DDV may be arranged on a flexible film coupled to the substrate SUB in the form of a chip on film (“COF”).

According to some embodiments, the display device DDa of FIG. 1B may include a plurality of data drivers DDVs. For example, the data drivers DDVs may be located on opposite sides of the display area DA in the second direction DR2. For example, the data drivers DDVs may be arranged along each of long sides of the display device DDa. However, embodiments according to the present disclosure are not limited thereto.

The gate driver GDV may be located in the peripheral area NDA on the substrate SUB. The gate driver GDV may generate a gate signal. The gate driver GDV may output the gate signal to the gate lines GL. The gate signal may be applied to the pixels PX through the gate lines GL. According to some embodiments, the gate drivers GDV may be located on opposite sides of the display area DA in the first direction DR1. However, embodiments according to the present disclosure are not limited thereto.

According to some embodiments, an emission driver generating an emission control signal may be further located in the peripheral area NDA. The emission control signal may be applied to the pixels PX through emission control lines.

The number or arrangement relationship of the data drivers DDVs and the number or arrangement relationship of the gate drivers GDVs illustrated in FIGS. 1A and 1B are merely examples, and embodiments according to the present disclosure are not limited thereto.

In addition, although FIG. 1A illustrates that the display device DD has a rectangular planar shape (or substantially rectangular planar shape) having short sides each extending in the first direction DR1 and long sides each extending in the second direction DR2, embodiments according to the present disclosure are not limited thereto. In addition, although FIG. 1B illustrates that the display device DDa has a rectangular planar shape (or substantially rectangular planar shape) having long sides each extending in the first direction DR1 and short sides each extending in the second direction DR2, embodiments according to the present disclosure are not limited thereto. That is, the planar shape of each of the display devices DD and DDa may be variously changed according to some embodiments.

The descriptions below with the drawings may be equally (or substantially equally) applied to the display device DD of FIG. 1A and the display device DDa of FIG. 1B. Therefore, for the convenience of description, the display devices DD and DDa are both referred to as the display device DD below.

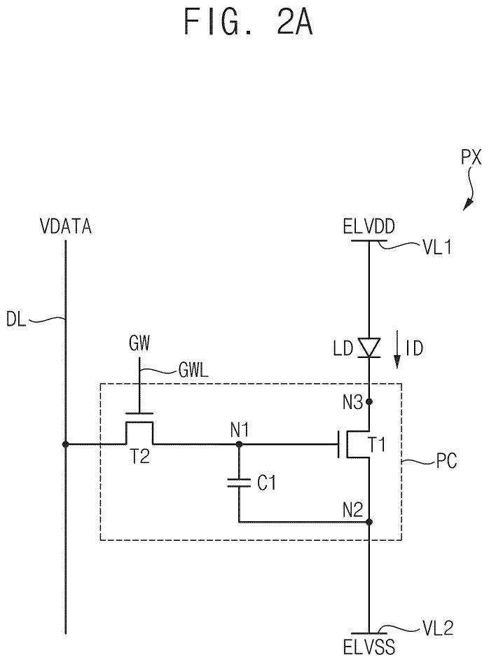

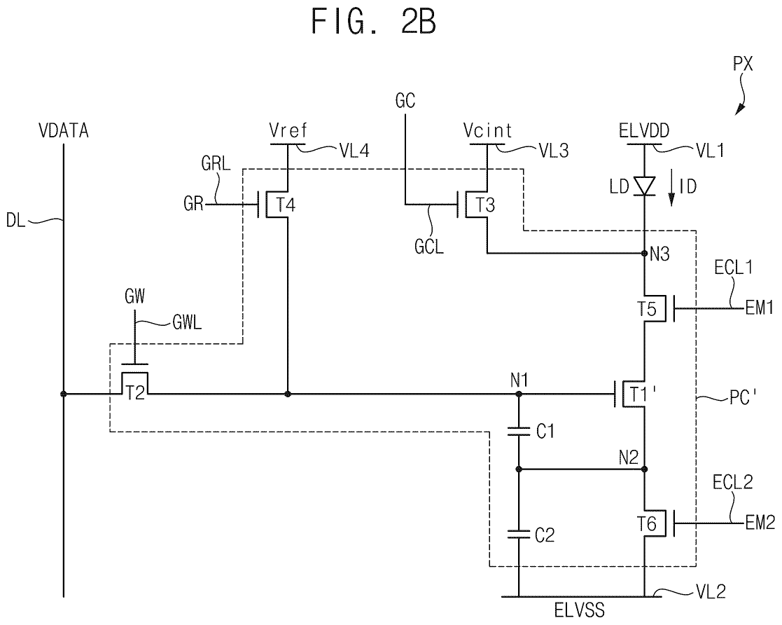

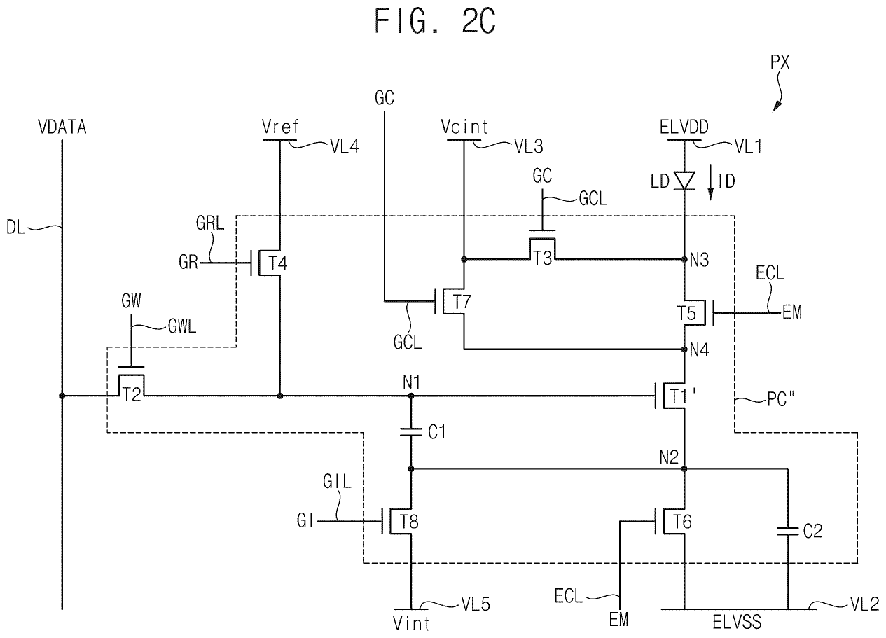

FIG. 2A is a circuit diagram illustrating an example of a circuit structure of a pixel included in the display device of FIGS. 1A and 1B. Although FIG. 2A illustrates various components in a pixel circuit according to some embodiments, embodiments according to the present disclosure are not limited thereto, and according to various embodiments, the pixel circuit may include additional components without departing from the spirit and scope of embodiments according to the present disclosure.

Referring to FIG. 2A, according to some embodiments, the pixel PX may include the light emitting element LD and the pixel driving circuit PC connected to the light emitting element LD. According to some embodiments, the pixel driving circuit PC may include a first transistor T1, a second transistor T2, and a first capacitor C1. In FIG. 2A, both the first transistor T1 and the second transistor T2 are illustrated as n-type transistors. However, embodiments according to the present disclosure are not limited thereto, and some of the first transistor T1 and the second transistor T2 may be an n-type transistor, and others may be a p-type transistor. For example, the first transistor T1 may be the n-type transistor, and the second transistor T2 may be the p-type transistor.

When the pixel PX includes the n-type transistor and the p-type transistor, an active pattern of the n-type transistor may include an oxide semiconductor material, and an active pattern of the p-type transistor may include a silicon semiconductor material. However, embodiments according to the present disclosure are not limited thereto, and both the active pattern of the n-type transistor and the active pattern of the p-type transistor may include a silicon semiconductor material.

The pixel driving circuit PC may be connected to a first gate line GWL, the data line DL, a first voltage line VL1, and a second voltage line VL2. The first gate line GWL may transfer a first gate signal GW. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level.

The first transistor T1 may include a gate terminal, a first terminal, and a second terminal. According to some embodiments, the first terminal of the first transistor T1 may be a source, and the second terminal of the first transistor T1 may be a drain. The gate terminal of the first transistor T1 may be connected to a first node N1. The first terminal of the first transistor T1 may be connected to a second node N2. The second terminal of the first transistor T1 may be connected to a third node N3. The second terminal of the first transistor T1 may be connected to the light emitting element LD. The first transistor T1 may provide a driving current ID to the light emitting element LD.

The second transistor T2 may include a gate terminal, a first terminal, and a second terminal. According to some embodiments, the first terminal of the second transistor T2 may be a source, and the second terminal of the second transistor T2 may be a drain. However, embodiments according to the present disclosure are not limited thereto, and the first terminal of the second transistor T2 may be a drain, and the second terminal of the second transistor T2 may be a source. The gate terminal of the second transistor T2 may be connected to the first gate line GWL. The first terminal of the second transistor T2 may be connected to the data line DL. The second terminal of the second transistor T2 may be connected to the first node N1.

The gate terminal of the second transistor T2 may receive the first gate signal GW through the first gate line GWL. The second transistor T2 may be turned on or off in response to the first gate signal GW. For example, when the second transistor T2 is the n-type transistor, the second transistor T2 may be turned off when the first gate signal GW has a negative voltage level, and the second transistor T2 may be turned on when the first gate signal GW has a positive voltage level. In addition, when the second transistor T2 is the p-type transistor, the second transistor T2 may be turned off when the first gate signal GW has a positive voltage level, and the second transistor T2 may be turned on when the first gate signal GW has a negative voltage level. The first terminal of the second transistor T2 may receive the data voltage VDATA through the data line DL. The second transistor T2 may provide the data voltage VDATA to the first node N1 while the second transistor T2 is turned on. Accordingly, the second transistor T2 may drive the first transistor T1.

The first capacitor C1 may include a first terminal and a second terminal. The first terminal of the first capacitor C1 may be connected to the first node N1. The second terminal of the first capacitor C1 may be connected to the second node N2. Current may be charged in or discharged from the first capacitor C1 according to the data voltage VDATA transferred to the first node N1.

The light emitting element LD may include an anode and a cathode. The anode of the light emitting element LD may be connected to the first voltage line VL1. The cathode of the light emitting element LD may be connected to the third node N3. For example, the cathode of the light emitting element LD may be connected to the second terminal of the first transistor T1.

FIG. 2B is a circuit diagram illustrating another example of a circuit structure of a pixel included in the display device of FIGS. 1A and 1B. Although FIG. 2B illustrates various components in a pixel circuit according to some embodiments, embodiments according to the present disclosure are not limited thereto, and according to various embodiments, the pixel circuit may include additional components or fewer components without departing from the spirit and scope of embodiments according to the present disclosure.

Compared to the embodiments of the circuit structure of the pixel PX described above with reference to FIG. 2A, a pixel driving circuit PC′ according to some embodiments of the circuit structure of the pixel PX described below with reference to FIG. 2B may further include third to sixth transistors T3, T4, T5, and T6 and a second capacitor C2. Therefore, some redundant descriptions of some components may be omitted or simplified.

Referring to FIG. 2B, according to some embodiments, the pixel PX may include the light emitting element LD and the pixel driving circuit PC′ connected to the light emitting element LD. According to some embodiments, the pixel driving circuit PC′ may include first to sixth transistors T1′, T2, T3, T4, T5, and T6, a first capacitor C1, and a second capacitor C2. In FIG. 2B, all of the first to sixth transistors T1′, T2, T3, T4, T5, and T6 are illustrated as n-type transistors. However, embodiments according to the present disclosure are not limited thereto, and some of the first to sixth transistors T1′, T2, T3, T4, T5, and T6 may be n-type transistors, and others may be p-type transistors. For example, the first transistor T1′ may be the n-type transistor, some of the second to sixth transistors T2, T3, T4, T5, and T6 may be the n-type transistors, and others may be the p-type transistors.

When the pixel PX includes the n-type transistor and the p-type transistor, an active pattern of the n-type transistor may include an oxide semiconductor material, and an active pattern of the p-type transistor may include a silicon semiconductor material. However, embodiments according to the present disclosure are not limited thereto, and both the active pattern of the n-type transistor and the active pattern of the p-type transistor may include a silicon semiconductor material.

The pixel driving circuit PC′ may be connected to first to third gate lines GWL, GCL, and GRL, a data line DL, first to fourth voltage lines VL1, VL2, VL3, and VL4, a first emission control line ECL1, and a second emission control line ECL2. The first gate line GWL may transfer a first gate signal GW. The second gate line GCL may transfer a second gate signal GC. The third gate line GRL may transfer a third gate signal GR. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level. The third voltage line VL3 may transfer a first initialization voltage Vcint. The fourth voltage line VL4 may transfer a reference voltage Vref. The reference voltage Vref may have a voltage level lower than a voltage level of the first power voltage ELVDD.

The first transistor T1′ of FIG. 2B may be the same (or substantially the same) as the first transistor T1 described above with reference to FIG. 2A, except that the first terminal is connected to the second voltage line VL2 through the six transistor T6 and the second terminal is connected to the light emitting element LD through the fifth transistor T5. Therefore, some redundant descriptions may be omitted or simplified. That is, the first transistor T1′ of the pixel driving circuit PC′ may be connected to the light emitting element LD through the fifth transistor T5 and may provide the driving current ID to the light emitting element LD through the fifth transistor T5.

The second transistor T2 of FIG. 2B may be the same (or substantially the same) as the second transistor T2 described above with reference to FIG. 2A. Accordingly, the description of the second transistor T2 of FIG. 2A may be equally applied to the second transistor T2 of FIG. 2B. That is, the second transistor T2 may drive the first transistor T1′ while the second transistor T2 is turned on.

The third transistor T3 may include a gate terminal, a first terminal, and a second terminal. According to some embodiments, the first terminal of the third transistor T3 may be a source, and the second terminal of the third transistor T3 may be a drain. However, embodiments according to the present disclosure are not limited thereto, and the first terminal of the third transistor T3 may be a drain, and the second terminal of the third transistor T3 may be a source. The gate terminal of the third transistor T3 may be connected to the second gate line GCL. The first terminal of the third transistor T3 may be connected to the third node N3. The second terminal of the third transistor T3 may be connected to the third voltage line VL3.

The gate terminal of the third transistor T3 may receive the second gate signal GC through the second gate line GCL. The third transistor T3 may be turned on or off in response to the second gate signal GC. For example, when the third transistor T3 is the n-type transistor, the third transistor T3 may be turned off when the second gate signal GC has a negative voltage level, and the third transistor T3 may be turned on when the second gate signal GC has a positive voltage level. In addition, when the third transistor T3 is the p-type transistor, the third transistor T3 may be turned off when the second gate signal GC has a positive voltage level, and the third transistor T3 may be turned on when the second gate signal GC has a negative voltage level. While the third transistor T3 is turned on, the third transistor T3 may provide the first initialization voltage Vcint to the third node N3. For example, the third transistor T3 may initialize a voltage of the cathode by providing the first initialization voltage Vcint to the cathode of the light emitting element LD.

The fourth transistor T4 may include a gate terminal, a first terminal, and a second terminal. According to some embodiments, the first terminal of the fourth transistor T4 may be a source, and the second terminal of the fourth transistor T4 may be a drain. However, embodiments according to the present disclosure are not limited thereto, and the first terminal of the fourth transistor T4 may be a drain, and the second terminal of the fourth transistor T4 may be a source. The gate terminal of the fourth transistor T4 may be connected to the third gate line GRL. The first terminal of the fourth transistor T4 may be connected to the first node N1. The second terminal of the fourth transistor T4 may be connected to the fourth voltage line VL4.

The gate terminal of the fourth transistor T4 may receive the third gate signal GR through the third gate line GRL. The fourth transistor T4 may be turned on or off in response to the third gate signal GR. For example, when the fourth transistor T4 is the n-type transistor, the fourth transistor T4 may be turned off when the third gate signal GR has a negative voltage level, and the fourth transistor T4 may be turned on when the third gate signal GR has a positive voltage level. In addition, when the fourth transistor T4 is the p-type transistor, the fourth transistor T4 may be turned off when the third gate signal GR has a positive voltage level, and the fourth transistor T4 may be turned on when the third gate signal GR has a negative voltage level. The second terminal of the fourth transistor T4 may receive the reference voltage Vref through the fourth voltage line VL4. While the fourth transistor T4 is turned on, the fourth transistor T4 may provide the reference voltage Vref to the first node N1.

The fifth transistor T5 may include a gate terminal, a first terminal, and a second terminal. According to some embodiments, the first terminal of the fifth transistor T5 may be a source, and the second terminal of the fifth transistor T5 may be a drain. However, embodiments according to the present disclosure are not limited thereto, and the first terminal of the fifth transistor T5 may be a drain, and the second terminal of the fifth transistor T5 may be a source. The gate terminal of the fifth transistor T5 may be connected to the first emission control line ECL1. The first terminal of the fifth transistor T5 may be connected to the second terminal of the first transistor T1′. The second terminal of the fifth transistor T5 may be connected to the third node N3. The second terminal of the fifth transistor T5 may be connected to the light emitting element LD.

The gate terminal of the fifth transistor T5 may receive the first emission control signal EM1 through the first emission control line ECL1. The fifth transistor T5 may be turned on or off in response to the first emission control signal EM1. For example, when the fifth transistor T5 is the n-type transistor, the fifth transistor T5 may be turned off when the first emission control signal EM1 has a negative voltage level, and the fifth transistor T5 may be turned on when the first emission control signal EM1 has a positive voltage level. In addition, when the fifth transistor T5 is the p-type transistor, the fifth transistor T5 may be turned off when the first emission control signal EM1 has a positive voltage level, and the fifth transistor T5 may be turned on when the first emission control signal EM1 has a negative voltage level. While the fifth transistor T5 is turned on, the fifth transistor T5 may electrically connect the first transistor T1′ and the light emitting element LD. For example, the fifth transistor T5 may electrically connect the second terminal of the first transistor T1′ and the cathode of the light emitting element LD in response to the first emission control signal EM1.

The sixth transistor T6 may include a gate terminal, a first terminal, and a second terminal. According to some embodiments, the first terminal of the sixth transistor T6 may be a source, and the second terminal of the sixth transistor T6 may be a drain. However, embodiments according to the present disclosure are not limited thereto, and the first terminal of the sixth transistor T6 may be a drain, and the second terminal of the sixth transistor T6 may be a source. The gate terminal of the sixth transistor T6 may be connected to the second emission control line ECL2. The first terminal of the sixth transistor T6 may be connected to the second voltage line VL2. The second terminal of the sixth transistor T6 may be connected to the second node N2.

The gate terminal of the sixth transistor T6 may receive the second emission control signal EM2 through the second emission control line ECL2. The sixth transistor T6 may be turned on or off in response to the second emission control signal EM2. For example, when the sixth transistor T6 is the n-type transistor, the sixth transistor T6 may be turned off when the second emission control signal EM2 has a negative voltage level, and the sixth transistor T6 may be turned on when the second emission control signal EM2 has a positive voltage level. In addition, when the sixth transistor T6 is the p-type transistor, the sixth transistor T6 may be turned off when the second emission control signal EM2 has a positive voltage level, and the sixth transistor T6 may be turned on when the second emission control signal EM2 has a negative voltage level. The first terminal of the sixth transistor T6 may receive the second power voltage ELVSS through the second voltage line VL2. While the sixth transistor T6 is turned on, the sixth transistor T6 may provide the second power voltage ELVSS to the second node N2.

Although FIG. 2B illustrates that the fifth transistor T5 and the sixth transistor T6 are independently driven by different emission control signals, embodiments according to the present disclosure are not limited thereto. For example, the first emission control signal EM1 and the second emission control signal EM2 may be provided as a single emission control signal, and the fifth transistor T5 and the sixth transistor T6 may be simultaneously turned on or off. In this case, the first emission control line ECL1 and the second emission control line ECL2 may be provided as a single emission control line.

The first capacitor C1 of FIG. 2B may be the same (or substantially the same) as the first capacitor C1 described above with reference to FIG. 2A. Accordingly, the description of the first capacitor C1 of FIG. 2A may be equally applied to the first capacitor C1 of FIG. 2B. That is, current may be charged in or discharged from the first capacitor C1 according to the data voltage VDATA transferred to the first node N1.

The second capacitor C2 may include a first terminal and a second terminal. The first terminal of the second capacitor C2 may be connected to the second node N2. The second terminal of the second capacitor C2 may be connected to the second voltage line VL2. For example, the second capacitor C2 may be connected in series to the first capacitor C1. The data voltage VDATA may be transferred to the first node N1 and may be voltage-divided due to the serial connection between the first capacitor C1 and the second capacitor C2 so that the divided data voltage VDATA may be transferred to the second node N2. Because the first transistor T1′ generates the driving current ID based on a voltage of the first node N1 and a voltage of the second node N2, a data range may be extended.

The light emitting element LD of FIG. 2B may be the same (or substantially the same) as the light emitting element LD described above with reference to FIG. 2A, except that the cathode is connected to the first terminal of the third transistor T3 and is connected to the second terminal of the first transistor T1′ through the fifth transistor T5. Therefore, some redundant descriptions may be omitted or simplified. That is, the cathode of the light emitting element LD may be connected to the second terminal of the first transistor T1′ through the fifth transistor T5. In addition, the cathode of the light emitting element LD may receive the first initialization voltage Vcint through the third transistor T3.

FIG. 2C is a circuit diagram illustrating still another example of a circuit structure of a pixel included in the display device of FIGS. 1A and 1B.

Compared to the embodiments of the circuit structure of the pixel PX described above with reference to FIG. 2B, a pixel driving circuit PC″ according to some embodiments of the circuit structure of the pixel PX described below with reference to FIG. 2C may further include seventh and eighth transistors T7 and T8. Therefore, some redundant descriptions of some components may be omitted or simplified.

Referring to FIG. 2C, according to some embodiments, the pixel PX may include the light emitting element LD and the pixel driving circuit PC″ connected to the light emitting element LD. According to some embodiments, the pixel driving circuit PC″ may include first to eighth transistors T1′, T2, T3, T4, T5, T6, T7, and T8, a first capacitor C1, and a second capacitor C2. In FIG. 2C, all of the first to eighth transistors T1′, T2, T3, T4, T5, T6, T7, and T8 are illustrated as n-type transistors. However, embodiments according to the present disclosure are not limited thereto, and some of the first to eighth transistors T1′, T2, T3, T4, T5, T6, T7, and T8 may be n-type transistors, and others may be p-type transistors. For example, the first transistor T1′ may be the n-type transistor, some of the second to eighth transistors T2, T3, T4, T5, T6, T7, and T8 may be the n-type transistors, and others may be the p-type transistors.

When the pixel PX includes the n-type transistor and the p-type transistor, an active pattern of the n-type transistor may include an oxide semiconductor material, and an active pattern of the p-type transistor may include a silicon semiconductor material. However, embodiments according to the present disclosure are not limited thereto, and both the active pattern of the n-type transistor and the active pattern of the p-type transistor may include a silicon semiconductor material.

The pixel driving circuit PC″ may be connected to first to fourth gate lines GWL, GCL, GRL, and GIL, a data line DL, first to fifth voltage lines VL1, VL2, VL3, VL4, and VL5, and an emission control line ECL. The first gate line GWL may transfer a first gate signal GW. The second gate line GCL may transfer a second gate signal GC. The third gate line GRL may transfer a third gate signal GR. The fourth gate line GIL may transfer a fourth gate signal GI. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level. The third voltage line VL3 may transfer a first initialization voltage Vcint. The fourth voltage line VL4 may transfer a reference voltage Vref. The reference voltage Vref may have a voltage level lower than a voltage level of the first power voltage ELVDD. The fifth voltage line VL5 may transfer a second initialization voltage Vint. The first initialization voltage Vcint and the second initialization voltage Vint may have different voltage levels from each other.

The first to sixth transistors T1′, T2, T3, T4, T5, and T6, the first capacitor C1, and the second capacitor C2 of FIG. 2C may be the same (or substantially the same) as the first to sixth transistors T1′, T2, T3, T4, T5, and T6, the first capacitor C1, and the second capacitor C2 described above with reference to FIG. 2B, respectively. Accordingly, the descriptions of the first to sixth transistors T1′, T2, T3, T4, T5, and T6, the first capacitor C1, and the second capacitor C2 of FIG. 2B may be equally applied to the first to sixth transistors T1′, T2, T3, T4, T5, and T6, the first capacitor C1, and the second capacitor C2 of FIG. 2C, respectively. Therefore, some redundant descriptions may be omitted.

Although FIG. 2C illustrates that the fifth transistor T5 and the sixth transistor T6 are simultaneously driven by the emission control signal EM, embodiments according to the present disclosure are not limited thereto. For example, as in FIG. 2B, the fifth transistor T5 and the sixth transistor T6 may be independently driven by different emission control signals (e.g., the first emission control signal EM1 and the second emission control signal EM2 of FIG. 2B). At this time, an emission control line connected to the fifth transistor T5 and an emission control line connected to the sixth transistor T6 may be emission control lines (e.g., the first emission control line ECL1 and the second emission control line ECL2 of FIG. 2B) that are distinct from each other.

The seventh transistor T7 may include a gate terminal, a first terminal, and a second terminal. According to some embodiments, the first terminal of the seventh transistor T7 may be a source, and the second terminal of the seventh transistor T7 may be a drain. However, embodiments according to the present disclosure are not limited thereto, and the first terminal of the seventh transistor T7 may be a drain, and the second terminal of the seventh transistor T7 may be a source. The gate terminal of the seventh transistor T7 may be connected to the second gate line GCL. The first terminal of the seventh transistor T7 may be connected to a fourth node N4. The second terminal of the seventh transistor T7 may be connected to the third voltage line VL3.

The gate terminal of the seventh transistor T7 may receive the second gate signal GC through the second gate line GCL. The seventh transistor T7 may be turned on or off in response to the second gate signal GC. For example, when the seventh transistor T7 is the n-type transistor, the seventh transistor T7 may be turned off when the second gate signal GC has a negative voltage level, and the seventh transistor T7 may be turned on when the second gate signal GC has a positive voltage level. In addition, when the seventh transistor T7 is the p-type transistor, the seventh transistor T7 may be turned off when the second gate signal GC has a positive voltage level, and the seventh transistor T7 may be turned on when the second gate signal GC has a negative voltage level. The second terminal of the seventh transistor T7 may receive the first initialization voltage Vcint through the third voltage line VL3. While the seventh transistor T7 is turned on, the seventh transistor T7 may provide the first initialization voltage Vcint to the fourth node N4. For example, the seventh transistor T7 may compensate for a threshold voltage (Vth) of the first transistor T1′ by providing the first initialization voltage Vcint to the fourth node N4.

Although FIG. 2C illustrates that the gate line connected to the third transistor T3 and the gate line connected to the seventh transistor T7 are provided as a single gate line (i.e., the second gate line GCL), embodiments according to the present disclosure are not limited thereto. For example, the gate line connected to the third transistor T3 and the gate line connected to the seventh transistor T7 may be gate lines that are distinct from each other.

In addition, although FIG. 2C illustrates that the third transistor T3 and the seventh transistor T7 are simultaneously driven by the second gate signal GC, embodiments according to the present disclosure are not limited thereto. For example, the third transistor T3 and the seventh transistor T7 may be independently driven by different gate signals. At this time, a gate line connected to the third transistor T3 and a gate line connected to the seventh transistor T7 may be gate lines that are distinct from each other.

The eighth transistor T8 may include a gate terminal, a first terminal, and a second terminal. According to some embodiments, the first terminal of the eighth transistor T8 may be a source, and the second terminal of the eighth transistor T8 may be a drain. However, embodiments according to the present disclosure are not limited thereto, and the first terminal of the eighth transistor T8 may be a drain, and the second terminal of the eighth transistor T8 may be a source. The gate terminal of the eighth transistor T8 may be connected to the fourth gate line GIL. The first terminal of the eighth transistor T8 may be connected to the second node N2. The second terminal of the eighth transistor T8 may be connected to the fifth voltage line VL5.

The gate terminal of the eighth transistor T8 may receive the fourth gate signal GI through the fourth gate line GIL. The eighth transistor T8 may be turned on or off in response to the fourth gate signal GI. For example, when the eighth transistor T8 is the n-type transistor, the eighth transistor T8 may be turned off when the fourth gate signal GI has a negative voltage level, and the eighth transistor T8 may be turned on when the fourth gate signal GI has a positive voltage level. In addition, when the eighth transistor T8 is the p-type transistor, the eighth transistor T8 may be turned off when the fourth gate signal GI has a positive voltage level, and the eighth transistor T8 may be turned on when the fourth gate signal GI has a negative voltage level. The second terminal of the eighth transistor T8 may receive the second initialization voltage Vint through the fifth voltage line VL5. While the eighth transistor T8 is turned on, the eighth transistor T8 may provide the second initialization voltage Vint to the second node N2.

The light emitting element LD of FIG. 2C may be the same (or substantially the same) as the light emitting element LD described above with reference to FIG. 2B. Accordingly, the description of the light emitting element LD of FIG. 2B may be equally applied to the light emitting element LD of FIG. 2C. Therefore, some redundant descriptions may be omitted.

As illustrated in FIGS. 2A, 2B, and 2C, according to some embodiments, the anode of the light emitting element LD may receive the first power voltage ELVDD through the first voltage line VL1, and the cathode of the light emitting element LD may be connected to the second terminal of the first transistor T1 (or T1′). That is, a potential of the cathode of the light emitting element LD may be controlled by being electrically connected to the first transistor T1 (or T1′).

Because the first voltage line VL1 provides the first power voltage ELVDD having a relatively high voltage level and the second voltage line VL2 provides the second power voltage ELVSS having a relatively low voltage level, when the first transistor T1 (or T1′) is the n-type transistor, the second terminal of the first transistor T1 (or T1′) may be a drain. That is, according to some embodiments, the cathode of the light emitting element LD may be connected to the drain of the first transistor T1 (or T1′).

When the first transistor T1 (or T1′) is the n-type transistor, if the anode of the light emitting element LD is connected to the source of first transistor T1 (or T1′), a source voltage of the first transistor T1 (or T1′) may shift due to deterioration of the light emitting element LD so that a gate-source voltage (Vgs) of the first transistor T1 (or T1′) may change. As a result, a range of change in the driving current ID may increase, an after-image defect may occur, and a lifespan of the display device may be relatively reduced.

According to some embodiments, the anode of the light emitting element LD may receive the first power voltage ELVDD, and the cathode of the light emitting element LD may be connected to the drain of the first transistor T1 (or T1′). Accordingly, even when the light emitting element LD deteriorates, the gate-source voltage (Vgs) of the first transistor T1 (or T1′) may not change. Accordingly, the range of change in the driving current ID due to the deterioration of the light emitting element LD may be relatively reduced. Therefore, the after-image defect of the display device DD depending on an increase in the time of use may be relatively reduced, and the lifespan of the display device DD may be relatively improved.

Meanwhile, the circuit structures of the pixels PX (e.g., the number or arrangement relationship of the transistors, the number or arrangement relationship of the capacitors) illustrated in FIGS. 2A, 2B, and 2C are only examples and may be variously changed according to some embodiments.

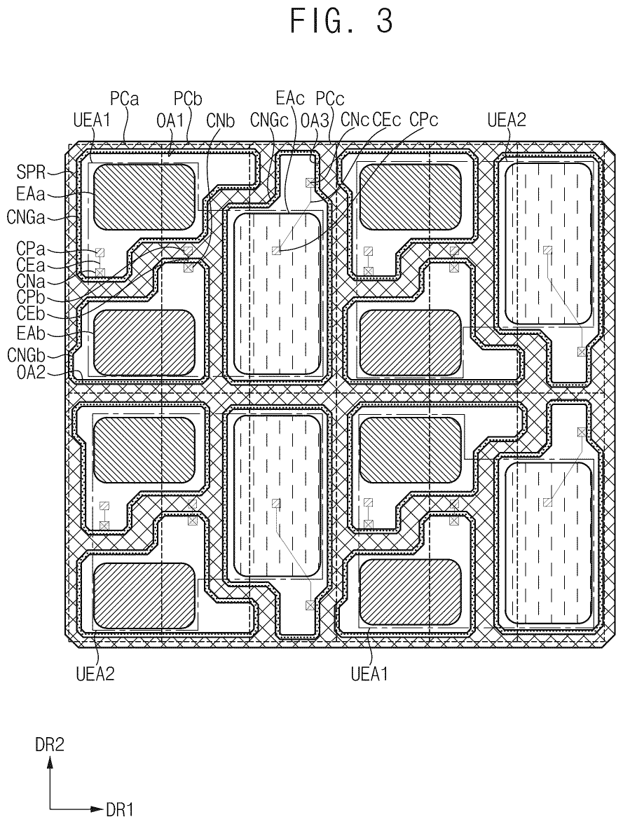

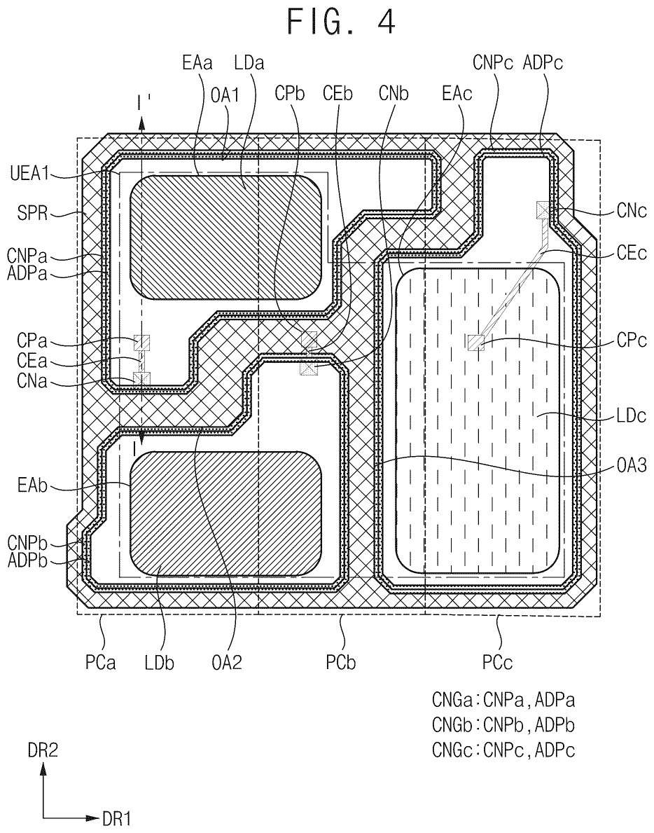

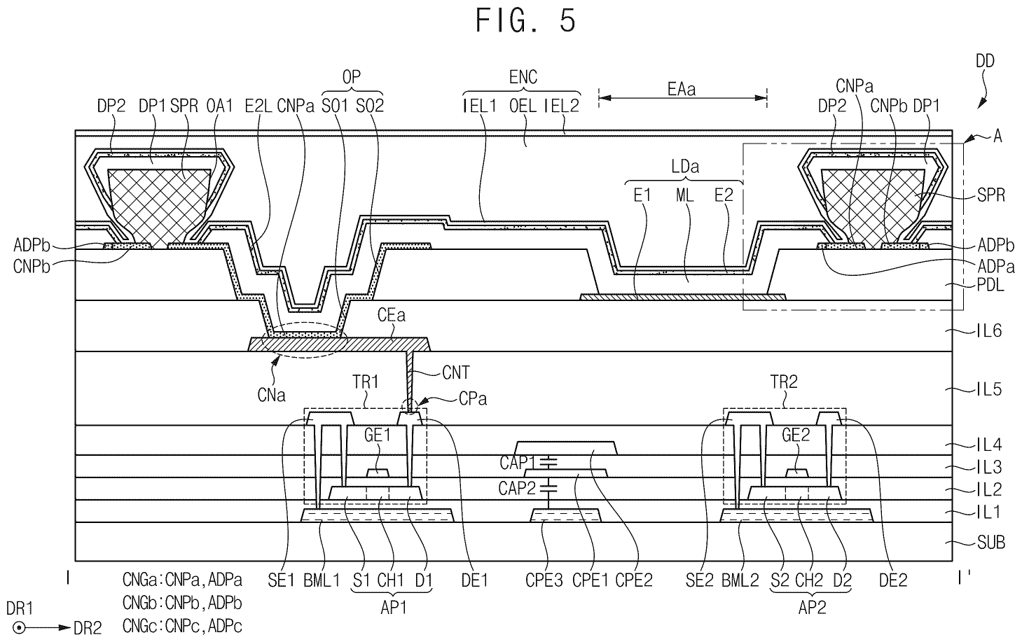

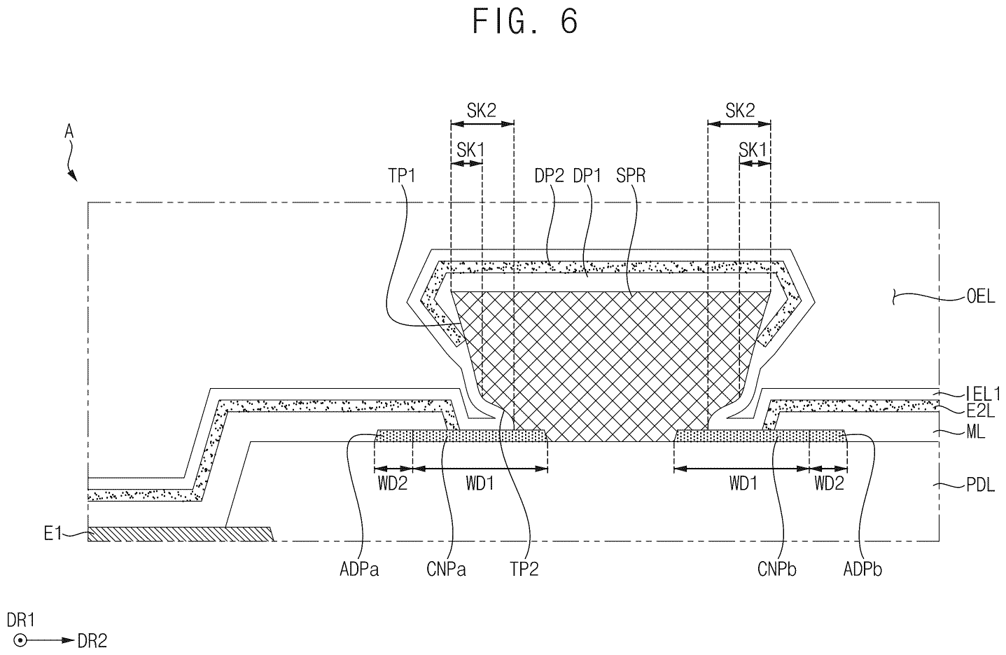

FIG. 3 is a plan view illustrating a portion of an area of the display device of FIGS. 1A and 1B. FIG. 4 is an enlarged plan view illustrating one unit emission area among the unit emission areas of FIG. 3. FIG. 5 is a cross-sectional view taken along the line I-I′ of FIG. 4. FIG. 6 is an enlarged cross-sectional view of the area A of FIG. 5.

For example, FIG. 3 illustrates an area in which four unit emission areas UEA1 and UEA2 forming a matrix of two rows and two columns are arranged, and FIG. 4 illustrates an enlarged view of a first unit emission area UEA1 among the unit emission areas UEA1 and UEA2. For convenience of description, some of components illustrated in FIG. 5 are omitted or emphasized in FIGS. 3 and 4.

Referring to FIGS. 3 and 4, the display device DD may include first to third pixel driving circuits PCa, PCb, and PCc, first to third light emitting elements LDa, LDb, and LDc, first to third connection electrodes CEa, CEb, and CEc, first to third connection structures CNGa, CNGb, and CNGc, and a separator SPR. The first connection structure CNGa may include a first connection pattern CNPa and a first additional connection pattern ADPa. The second connection structure CNGb may include a second connection pattern CNPb and a second additional connection pattern ADPb. The third connection structure CNGc may include a third connection pattern CNPc and a third additional connection pattern ADPc.

Each of the first to third pixel driving circuits PCa, PCb, and PCc may correspond to at least one of the pixel driving circuits PC, PC′, and PC″ described above with reference to FIGS. 2A, 2B, and 2C. That is, each of the first to third pixel driving circuits PCa, PCb, and PCc may include at least one transistor and at least one capacitor. For example, each of the first to third pixel driving circuits PCa, PCb, and PCc may include a first transistor TR1, a second transistor TR2, a first capacitor CAP1, and a second capacitor CAP2 illustrated in FIG. 5.

In this case, the first transistor TR1 of FIG. 5 may be a transistor connected to the light emitting element through the connection electrode and the connection pattern. For example, when each of the first to third pixel driving circuits PCa, PCb, and PCc is the pixel driving circuit PC of FIG. 2A, the first transistor TR1 may be the first transistor T1 of FIG. 2A, and the second transistor TR2 may be the second transistor T2 of FIG. 2A. In addition, when each of the first to third pixel driving circuits PCa, PCb, and PCc is the pixel driving circuit PC′ of FIG. 2B, the first transistor TR1 may be the fifth transistor T5 of FIG. 2B, and the second transistor TR2 may be one of the first, second, third, fourth, and sixth transistors T1′, T2, T3, T4, and T6 of FIG. 2B. In addition, when each of the first to third pixel driving circuits PCa, PCb, and PCc is the pixel driving circuit PC″ of FIG. 2C, the first transistor TR1 may be the fifth transistor T5 of FIG. 2C, and the second transistor TR2 may be one of the first, second, third, fourth, sixth, seventh, and eighth transistors T1′, T2, T3, T4, T6, T7, and T8 of FIG. 2C. However, embodiments according to the present disclosure are not limited thereto.

According to some embodiments, the first capacitor CAP1 of FIG. 5 may correspond to the first capacitor C1 of FIGS. 2A, 2B, and 2C, and the second capacitor CAP2 of FIG. 5 may correspond to the second capacitor C2 of FIGS. 2B and 2C. That is, when each of the first to third pixel driving circuits PCa, PCb, and PCc is the pixel driving circuit PC of FIG. 2A, the second capacitor CAP2 may be omitted. However, embodiments according to the present disclosure are not limited thereto, and according to some embodiments, the first capacitor CAP1 of FIG. 5 may correspond to the second capacitor C2 of FIGS. 2B and 2C, and the second capacitor CAP2 of FIG. 5 may correspond to the first capacitor C1 of FIGS. 2A, 2B, and 2C. In this case, when each of the first to third pixel driving circuits PCa, PCb, and PCc is the pixel driving circuit PC of FIG. 2A, the first capacitor CAP1 may be omitted.

The first transistor TR1, the second transistor TR2, the first capacitor CAP1, and the second capacitor CAP2 will be described in more detail later with reference to FIG. 5.

FIGS. 3 and 4 illustrate that the first to third pixel driving circuits PCa, PCb, and PCc each has a rectangular shape and are sequentially arranged along the first direction DR1. However, embodiments according to the present disclosure are not limited thereto, and the shape and arrangement of the first to third pixel driving circuits PCa, PCb, and PCc may be variously changed according to some embodiments.

Each of the first to third light emitting elements LDa, LDb, and LDc may correspond to the light emitting element LD described above with reference to FIGS. 2A, 2B, and 2C. For example, the first to third light emitting elements LDa, LDb, and LDc may include a first electrode (e.g., a first electrode E1 of FIG. 5), an intermediate layer (e.g., an intermediate layer ML of FIG. 5) located on the first electrode, and an electrode layer (e.g., an electrode layer E2L of FIG. 5) located on the intermediate layer. According to some embodiments, the first electrode may function as the anode of FIGS. 2A, 2B, and 2C, and the electrode layer may function as the cathode of FIGS. 2A, 2B, and 2C.

According to some embodiments, the electrode layer may be separated (or disconnected) into a plurality of second electrodes by the separator SPR. For example, the electrode layer may be separated (or disconnected) into a second electrode (e.g., a second electrode E2 of FIG. 5), of the first light emitting element LDa, a second electrode of the second light emitting element LDb, and a second electrode of the third light emitting element LDc. This will be described in more detail later.

The first to third light emitting elements LDa, LDb, and LDc may be connected to the first to third pixel driving circuits PCa, PCb, and PCc, respectively. For example, the first light emitting element LDa may be connected to the first pixel driving circuit PCa, the second light emitting element LDb may be connected to the second pixel driving circuit PCb, and the third light emitting element LDc may be connected to the third pixel driving circuit PCc. Accordingly, the first pixel driving circuit PCa and the first light emitting element LDa may form one pixel, the second pixel driving circuit PCb and the second light emitting element LDb may form one pixel, and the third pixel driving circuit PCc and the third light emitting element LDc may form one pixel.

The first to third light emitting elements LDa, LDb, and LDc may emit light of different colors. For example, the first light emitting element LDa may emit red light, the second light emitting element LDb may emit green light, and the third light emitting element LDc may emit blue light. However, embodiments according to the present disclosure are not limited thereto.

According to some embodiments, the display device DD may include the first unit emission area UEA1 and the second unit emission area UEA2. The first unit emission area UEA1 and the second unit emission area UEA2 may be defined in a matrix form in the first direction DR1 and the second direction DR2. Although FIG. 3 illustrates only four unit emission areas, a plurality of unit emission areas may be defined in a matrix form along the first direction DR1 and the second direction DR2 in the entire display area (DA, see FIGS. 1A and 1B).

The first to third light emitting elements LDa, LDb, and LDc adjacent to each other may be located in each of the first unit emission area UEA1 and the second unit emission area UEA2. For example, first to third emission areas EAa, EAb, and EAc adjacent to each other may be defined in each of the first unit emission area UEA1 and the second unit emission area UEA2, and the first to third light emitting elements LDa, LDb, and LDc may be located in the first to third emission areas EAa, EAb, and EAc, respectively.

The first to third emission areas EAa, EAb, and EAc may be defined by pixel openings of a pixel defining layer (PDL, see FIG. 5) described hereinafter. That is, each of the first to third emission areas EAa, EAb, and EAc may be an area where light is emitted from the light emitting element. For example, the first light emitting element LDa may be located in the first emission area EAa, and the first emission area EAa may be an area where light is emitted from the first light emitting element LDa. In addition, the second light emitting element LDb may be located in the second emission area EAb, and the second emission area EAb may be an area where light is emitted from the second light emitting element LDb. In addition, the third light emitting element LDc may be located in the third emission area EAc, and the third emission area EAc may be an area where light is emitted from the third light emitting element LDc.

According to some embodiments, the first unit emission area UEA1 and the second unit emission area UEA2 may be distinguished based on the arrangement relationship between the first to third light emitting elements LDa, LDb, and LDc (or the arrangement relationship between the first to third emission areas EAa, EAb, and EAc). That is, the arrangement relationship between the first to third light emitting elements LDa, LDb, and LDc (or the first to third emission areas EAa, EAb, and EAc) may be the same for each first unit emission area UEA1, and the arrangement relationship between the first to third light emitting elements LDa, LDb, and LDc (or the first to third emission areas EAa, EAb, and EAc) may be the same for each second unit emission area UEA2.

According to some embodiments, as illustrated in FIG. 3, the first unit emission areas UEA1 and the second unit emission areas UEA2 may be alternately arranged along the first direction DR1 (i.e., a row direction) and the second direction DR2 (i.e., a column direction). However, embodiments according to the present disclosure are not limited thereto, and the number of different unit emission areas included in the display device DD or the arrangement relationship between the unit emission areas may be variously changed according to some embodiments.

FIGS. 3 and 4 illustrate that the first to third emission areas EAa, EAb, and EAc are located in an S-stripe structure. However, embodiments according to the present disclosure are not limited thereto, and the arrangement of the first to third emission areas EAa, EAb, and EAc may be variously changed according to some embodiments.

Hereinafter, a connection relationship between the first to third light emitting elements LDa, LDb, and LDc and the first to third pixel driving circuits PCa, PCb, and PCc will be described in more detail, focusing on the first unit emission area UEA1 of FIG. 4. The following description of the connection relationship between the first to third light emitting elements LDa, LDb, and LDc and the first to third pixel driving circuits PCa, PCb, and PCc may be equally (or substantially equally) applied to all unit emission areas.

As described above, the display device DD may include the first to third connection electrodes CEa, CEb, and CEc and the first to third connection structures CNGa, CNGb, and CNGc. The first connection structure CNGa may include the first connection pattern CNPa and the first additional connection pattern ADPa. The second connection structure CNGb may include the second connection pattern CNPb and the second additional connection pattern ADPb. The third connection structure CNGc may include the third connection pattern CNPc and the third additional connection pattern ADPc.

The first connection electrode CEa and the first connection pattern CNPa may electrically connect the first light emitting element LDa and the first pixel driving circuit PCa. The second connection electrode CEb and the second connection pattern CNPb may electrically connect the second light emitting element LDb and the second pixel driving circuit PCb. The third connection electrode CEc and the third connection pattern CNPc may electrically connect the third light emitting element LDc and the third pixel driving circuit PCc.

The first to third connection electrodes CEa, CEb, and CEc may include a conductive material such as a metal, an alloy, a conductive metal oxide, a conductive metal nitride, a transparent conductive oxide, or the like. Examples of the conductive material that may be used as the first to third connection electrodes CEa, CEb, and CEc may include gold (Au), silver (Ag), aluminum (AI), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing Al, an alloy containing Ag, an alloy containing Cu, an alloy containing Mo, aluminum nitride (AlₓN_{y}), tungsten nitride (WₓN_{y}), titanium nitride (TiₓN_{y}), chromium nitride (CrₓN_{y}), tantalum nitride (TaₓN_{y}), tin oxide (SnO), gallium oxide (GaO), indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), aluminum zinc oxide (AZO), or the like. These may be used alone or in combination with each other. According to some embodiments, each of the first to third connection electrodes CEa, CEb, and CEc may have a single-layer structure or a multi-layer structure in which a plurality of conductive layers are stacked.

According to some embodiments, the first to third connection patterns CNPa, CNPb, and CNPc may include a transparent conductive oxide. Examples of the transparent conductive oxide that may be used as the first to third connection patterns CNPa, CNPb, and CNPc may include indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), aluminum zinc oxide (AZO), or the like. These may be used alone or in combination with each other.

According to some embodiments, the first to third connection patterns CNPa, CNPb, and CNPc may include a conductive material such as a metal, an alloy, a conductive metal nitride, or the like. Examples of the conductive material that may be used as the first to third connection patterns CNPa, CNPb, and CNPc may include gold (Au), silver (Ag), aluminum (AI), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing Al, an alloy containing Ag, an alloy containing Cu, an alloy containing Mo, aluminum nitride (AlₓN_{y}), tungsten nitride (WₓN_{y}), titanium nitride (TiₓN_{y}), chromium nitride (CrₓN_{y}), tantalum nitride (TaₓN_{y}), or the like. These may be used alone or in combination with each other.

According to some embodiments, each of the first to third connection patterns CNPa, CNPb, and CNPc may have a single-layer structure or a multi-layer structure in which a plurality of conductive layers are stacked.

According to some embodiments, the first to third additional connection patterns ADPa, ADPb, and ADPc may include a transparent conductive oxide. However, embodiments according to the present disclosure are not limited thereto, and the first to third additional connection patterns ADPa, ADPb, and ADPc may include a conductive material such as a metal, an alloy, a conductive metal nitride, or the like.

According to some embodiments, each of the first to third additional connection patterns ADPa, ADPb, and ADPc may have a single-layer structure or a multi-layer structure in which a plurality of conductive layers are stacked.

According to some embodiments, the first to third additional connection patterns ADPa, ADPb, and ADPc may include the same material as the first to third connection patterns CNPa, CNPb, and CNPc. The first to third additional connection patterns ADPa, ADPb, and ADPc may be formed integrally with the first to third connection patterns CNPa, CNPb, and CNPc.

The first connection electrode CEa may include a first circuit connection portion CPa and a first light emitting connection portion CNa.

The first circuit connection portion CPa may be a portion, which is connected to the first pixel driving circuit PCa, of the first connection electrode CEa. For example, the first circuit connection portion CPa may be a portion, which is connected to the first transistor (TR1, see FIG. 5) of the first pixel driving circuit PCa, of the first connection electrode CEa. Accordingly, a position of the first circuit connection portion CPa may correspond to a position of the first transistor TR1 of the first pixel driving circuit PCa. For example, the position of the first circuit connection portion CPa may correspond to a position of a contact hole (CNT, see FIG. 5) that exposes the first transistor TR1 of the first pixel driving circuit PCa and penetrates the fifth insulating layer (IL5, see FIG. 5).

The first light emitting connection portion CNa may be a portion, which is connected to the first connection pattern CNPa, of the first connection electrode CEa. For example, the first light emitting connection portion CNa may be a portion, which is exposed by the sixth insulating layer (IL6, see FIG. 5) and the pixel defining layer (PDL, see FIG. 5) for being connected to the first connection pattern CNPa, of the first connection electrode CEa. Accordingly, a position of the first light emitting connection portion CNa may correspond to a position of an opening (OP, see FIG. 5) that exposes the first connection electrode CEa and penetrates the pixel defining layer and the sixth insulating layer. In a plan view, the first light emitting connection portion CNa may not overlap the first emission area EAa. For example, in a plan view, the first light emitting connection portion CNa may be located between the first emission area EAa and the separator SPR.

The first connection pattern CNPa may be connected to the first connection electrode CEa. For example, the first connection pattern CNPa may contact the first light emitting connection portion CNa of the first connection electrode CEa. However, embodiments according to the present disclosure are not limited thereto, and the first connection pattern CNPa may not directly contact the first connection electrode CEa. For example, the first connection pattern CNPa may contact a capping layer that contacts the first light emitting connection portion CNa of the first connection electrode CEa, and may be connected to the first light emitting connection portion CNa of the first connection electrode CEa through the capping layer. The capping layer may include a conductive material. For example, the capping layer may be simultaneously (or substantially simultaneously) formed with the first electrode (E1, see FIG. 5) and may include the same material as the first electrode.

The first connection pattern CNPa may not overlap the first emission area EAa in a plan view. According to some embodiments, the first connection pattern CNPa may surround at least a portion of the first emission area EAa in a plan view. For example, the first connection pattern CNPa may have a closed ring shape that entirely surrounds the first emission area EAa in a plan view. However, embodiments according to the present disclosure are not limited thereto.

The second electrode (E2, see FIG. 5) of the first light emitting element LDa may be connected to the first connection pattern CNPa. For example, the second electrode of the first light emitting element LDa may contact the first connection pattern CNPa. Accordingly, the first connection pattern CNPa may electrically connect the first connection electrode CEa and the second electrode of the first light emitting element LDa. As a result, the second electrode of the first light emitting element LDa may be electrically connected to the first pixel driving circuit PCa through the first connection electrode CEa and the first connection pattern CNPa.

According to some embodiments, in a plan view, a profile of an area where the second electrode of the first light emitting element LDa and the first connection pattern CNPa contact each other may be the same (or substantially the same) as or similar to a profile of an edge of the first connection pattern CNPa. For example, when the first connection pattern CNPa has a closed ring shape that entirely surrounds the first emission area EAa in a plan view, the area where the second electrode of the first light emitting element LDa and the first connection pattern CNPa contact each other may have a closed ring shape in a plan view. That is, the second electrode of the first light emitting element LDa and the first connection pattern CNPa may contact each other at a position not overlapping the first emission area EAa. Accordingly, the second electrode of the first light emitting element LDa and the first pixel driving circuit PCa may be electrically connected to each other through the first connection pattern CNPa and the first connection electrode CEa without reducing the size of the first emission area EAa (i.e., an aperture ratio).

The first additional connection pattern ADPa may extend from the first connection pattern CNPa. The first additional connection pattern ADPa may contact the first connection pattern CNPa. According to some embodiments, the first additional connection pattern ADPa may include the same material as the first connection pattern CNPa and may be integrally formed with the first connection pattern CNPa.

The first additional connection pattern ADPa may not overlap the first emission area EAa in a plan view. According to some embodiments, the first additional connection pattern ADPa may surround at least a portion of the first emission area EAa in a plan view. For example, the first additional connection pattern ADPa may have a closed ring shape that entirely surrounds the first emission area EAa in a plan view. However, embodiments according to the present disclosure are not limited thereto.

The first additional connection pattern ADPa may be located between the first connection pattern CNPa and the first emission area EAa in a plan view. According to some embodiments, the first connection pattern CNPa may surround at least a portion of the first additional connection pattern ADPa in a plan view. For example, the first connection pattern CNPa may have a closed ring shape that entirely surrounds the first additional connection pattern ADPa in a plan view. However, embodiments according to the present disclosure are not limited thereto.

The second connection electrode CEb may include a second circuit connection portion CPb and a second light emitting connection portion CNb.

The second circuit connection portion CPb may be a portion, which is connected to the second pixel driving circuit PCb, of the second connection electrode CEb. For example, the second circuit connection portion CPb may be a portion, which is connected to the first transistor (TR1, see FIG. 5) of the second pixel driving circuit PCb, of the second connection electrode CEb. Accordingly, a position of the second circuit connection portion CPb may correspond to a position of the first transistor of the second pixel driving circuit PCb. For example, the position of the second circuit connection portion CPb may correspond to a position of a contact hole that exposes the first transistor of the second pixel driving circuit PCb and penetrates the fifth insulating layer (IL5, see FIG. 5).

The second light emitting connection portion CNb may be a portion, which is connected to the second connection pattern CNPb, of the second connection electrode CEb. For example, the second light emitting connection portion CNb may be a portion, which is exposed by the sixth insulating layer (IL6, see FIG. 5) and the pixel defining layer (PDL, see FIG. 5) for being connected to the second connection pattern CNPb, of the second connection electrode CEb. Accordingly, a position of the second light emitting connection portion CNb may correspond to a position of an opening that exposes the second connection electrode CEb and penetrates the pixel defining layer and the sixth insulating layer. In a plan view, the second light emitting connection portion CNb may not overlap the second emission area EAb. For example, the second light emitting connection portion CNb may be located between the second emission area EAb and the separator SPR.

According to some embodiments, the second connection electrode CEb may be spaced apart from the first connection electrode CEa in a plan view. In other words, the first connection electrode CEa and the second connection electrode CEb may be electrodes that are distinct from each other.

The second connection pattern CNPb may be connected to the second connection electrode CEb. For example, the second connection pattern CNPb may contact the second light emitting connection portion CNb of the second connection electrode CEb. However, embodiments according to the present disclosure are not limited thereto, and the second connection pattern CNPb may not directly contact the second connection electrode CEb. For example, the second connection pattern CNPb may contact a capping layer that contacts the second light emitting connection portion CNb of the second connection electrode CEb, and may be connected to the second light emitting connection portion CNb of the second connection electrode CEb through the capping layer. The capping layer may include a conductive material. For example, the capping layer may be simultaneously (or substantially simultaneously) formed with the first electrode (E1, see FIG. 5) and may include the same material as the first electrode.

The second connection pattern CNPb may not overlap the second emission area EAb in a plan view. According to some embodiments, the second connection pattern CNPb may surround at least a portion of the second emission area EAb in a plan view. For example, the second connection pattern CNPb may have a closed ring shape that entirely surrounds the second emission area EAb in a plan view. However, embodiments according to the present disclosure are not limited thereto.

According to some embodiments, the second connection pattern CNPb may be spaced apart from the first connection pattern CNPa in a plan view. In other words, the first connection pattern CNPa and the second connection pattern CNPb may be patterns that are distinct from each other.

The second electrode of the second light emitting element LDb may be connected to the second connection pattern CNPb. For example, the second electrode of the second light emitting element LDb may contact the second connection pattern CNPb. Accordingly, the second connection pattern CNPb may electrically connect the second connection electrode CEb and the second electrode of the second light emitting element LDb. As a result, the second electrode of the second light emitting element LDb may be electrically connected to the second pixel driving circuit PCb through the second connection electrode CEb and the second connection pattern CNPb.

According to some embodiments, in a plan view, a profile of an area where the second electrode of the second light emitting element LDb and the second connection pattern CNPb contact each other may be the same (or substantially the same) as or similar to a profile of an edge of the second connection pattern CNPb. For example, when the second connection pattern CNPb has a closed ring shape that entirely surrounds the second emission area EAb in a plan view, the area where the second electrode of the second light emitting element LDb and the second connection pattern CNPb contact each other may have a closed ring shape in a plan view. That is, the second electrode of the second light emitting element LDb and the second connection pattern CNPb may contact each other at a position not overlapping the second emission area EAb. Accordingly, the second electrode of the second light emitting element LDb and the second pixel driving circuit PCb may be electrically connected to each other through the second connection pattern CNPb and the second connection electrode CEb without reducing the size of the second emission area EAb (i.e., an aperture ratio).

The second additional connection pattern ADPb may extend from the second connection pattern CNPb. The second additional connection pattern ADPb may contact the second connection pattern CNPb. According to some embodiments, the second additional connection pattern ADPb may include the same material as the second connection pattern CNPb and may be integrally formed with the second connection pattern CNPb.

The second additional connection pattern ADPb may not overlap the second emission area EAb in a plan view. According to some embodiments, the second additional connection pattern ADPb may surround at least a portion of the second emission area EAb in a plan view. For example, the second additional connection pattern ADPb may have a closed ring shape that entirely surrounds the second emission area EAb in a plan view. However, embodiments according to the present disclosure are not limited thereto.

The second additional connection pattern ADPb may be located between the second connection pattern CNPb and the second emission area EAb in a plan view. According to some embodiments, the second connection pattern CNPb may surround at least a portion of the second additional connection pattern ADPb in a plan view. For example, the second connection pattern CNPb may have a closed ring shape that entirely surrounds the second additional connection pattern ADPb in a plan view. However, embodiments according to the present disclosure are not limited thereto.

According to some embodiments, the second additional connection pattern ADPb may be spaced apart from the first additional connection pattern ADPa in a plan view. In other words, the first additional connection pattern ADPa and the second additional connection pattern ADPb may be patterns that are distinct from each other.

The third connection electrode CEc may include a third circuit connection portion CPc and a third light emitting connection portion CNc.

The third circuit connection portion CPc may be a portion, which is connected to the third pixel driving circuit PCc, of the third connection electrode CEc. For example, the third circuit connection portion CPc may be a portion, which is connected to the first transistor (TR1, see FIG. 5) of the third pixel driving circuit PCc, of the third connection electrode CEc. Accordingly, a position of the third circuit connection portion CPc may correspond to a position of the first transistor TR1 of the third pixel driving circuit PCc. For example, the position of the third circuit connection portion CPc may correspond to a position of a contact hole that exposes the first transistor of the third pixel driving circuit PCc and penetrates the fifth insulating layer (IL5, see FIG. 5).

The third light emitting connection portion CNc may be a portion, which is connected to the third connection pattern CNPc, of the third connection electrode CEc. For example, the third light emitting connection portion CNc may be a portion, which is exposed by the sixth insulating layer (IL6, see FIG. 5) and the pixel defining layer (PDL, see FIG. 5) for being connected to the third connection pattern CNPc, of the third connection electrode CEc. Accordingly, a position of the third light emitting connection portion CNc may correspond to a position of an opening that exposes the third connection electrode CEc and penetrates the pixel defining layer and the sixth insulating layer. In a plan view, the third light emitting connection portion CNc may not overlap the third emission area EAc. For example, the third light emitting connection portion CNc may be located between the third emission area EAc and the separator SPR.

According to some embodiments, the third connection electrode CEc may be spaced apart from the first connection electrode CEa and the second connection electrode CEb in a plan view. In other words, the first connection electrode CEa, the second connection electrode CEb, and the third connection electrode CEc may be electrodes that are distinct from each other.

The third connection pattern CNPc may be connected to the third connection electrode CEc. For example, the third connection pattern CNPc may contact the third light emitting connection portion CNc of the third connection electrode CEc. However, embodiments according to the present disclosure are not limited thereto, and the third connection pattern CNPc may not directly contact the third connection electrode CEc. For example, the third connection pattern CNPc may contact a capping layer that contacts the third light emitting connection portion CNc of the third connection electrode CEc, and may be connected to the third light emitting connection portion CNc of the third connection electrode CEc through the capping layer. The capping layer may include a conductive material. For example, the capping layer may be simultaneously (or substantially simultaneously) formed with the first electrode (E1, see FIG. 5) and may include the same material as the first electrode.

The third connection pattern CNPc may not overlap the third emission area EAc in a plan view. According to some embodiments, the third connection pattern CNPc may surround at least a portion of the third emission area EAc in a plan view. For example, the third connection pattern CNPc may have a closed ring shape that entirely surrounds the third emission area EAc in a plan view. However, embodiments according to the present disclosure are not limited thereto.

According to some embodiments, the third connection pattern CNPc may be spaced apart from the first connection pattern CNPa and the second connection pattern CNPb. In other words, the first connection pattern CNPa, the second connection pattern CNPb, and the third connection pattern CNPc may be patterns that are distinct from each other.

The second electrode of the third light emitting element LDc may be connected to the third connection pattern CNPc. For example, the second electrode of the third light emitting element LDc may contact the third connection pattern CNPc. Accordingly, the third connection pattern CNPc may electrically connect the third connection electrode CEc and the second electrode of the third light emitting element LDc. As a result, the second electrode of the third light emitting element LDc may be electrically connected to the third pixel driving circuit PCc through the third connection electrode CEc and the third connection pattern CNPc.

According to some embodiments, in a plan view, a profile of an area where the second electrode of the third light emitting element LDc and the third connection pattern CNPc contact each other may be the same (or substantially the same) as or similar to a profile of an edge of the third connection pattern CNPc. For example, when the third connection pattern CNPc has a closed ring shape that entirely surrounds the third emission area EAc in a plan view, the area where the second electrode of the third light emitting element LDc and the third connection pattern CNPc contact each other may have a closed ring shape in a plan view. That is, the second electrode of the third light emitting element LDc and the third connection pattern CNPc may contact each other at a position not overlapping the third emission area EAc. Accordingly, the second electrode of the third light emitting element LDc and the third pixel driving circuit PCc may be electrically connected to each other through the third connection pattern CNPc and the third connection electrode CEc without reducing the size of the third emission area EAc (i.e., an aperture ratio).

The third additional connection pattern ADPc may extend from the third connection pattern CNPc. The third additional connection pattern ADPc may contact the third connection pattern CNPc. According to some embodiments, the third additional connection pattern ADPc may include the same material as the third connection pattern CNPc and may be integrally formed with the third connection pattern CNPc.

The third additional connection pattern ADPc may not overlap the third emission area EAc in a plan view. According to some embodiments, the third additional connection pattern ADPc may surround at least a portion of the third emission area EAc in a plan view. For example, the third additional connection pattern ADPc may have a closed ring shape that entirely surrounds the third emission area EAc in a plan view. However, embodiments according to the present disclosure are not limited thereto.

The third additional connection pattern ADPc may be located between the third connection pattern CNPc and the third emission area EAc in a plan view. According to some embodiments, the third connection pattern CNPc may surround at least a portion of the third additional connection pattern ADPc in a plan view. For example, the third connection pattern CNPc may have a closed ring shape that entirely surrounds the third additional connection pattern ADPc in a plan view. However, embodiments according to the present disclosure are not limited thereto.

According to some embodiments, the third additional connection pattern ADPc may be spaced apart from the first additional connection pattern ADPa and the second additional connection pattern ADPb in a plan view. In other words, the first additional connection pattern ADPa, the second additional connection pattern ADPb, and the third additional connection pattern ADPc may be patterns that are distinct from each other.

According to some embodiments, the second electrodes may contact the first to third connection patterns CNPa, CNPb, and CNPc, respectively, at positions where the second electrodes do not overlap the first to third emission areas EAa, EAb, and EAc, respectively. Accordingly, the second electrodes may contact the first to third connection patterns CNPa, CNPb, and CNPc, respectively, without reducing the size of each of the first to third emission areas EAa, EAb, and EAc (i.e., an aperture ratio).

In addition, according to some embodiments, the second electrodes may be electrically connected to the first to third pixel driving circuits PCa, PCb, and PCc through the first to third connection electrodes CEa, CEb, and CEc and the first to third connection patterns CNPa, CNPb, and CNPc, respectively. Accordingly, a limitation of the design of each of the first to third pixel driving circuits PCa, PCb, and PCc due to the positions, shapes, and sizes of the first to third emission areas EAa, EAb, and EAc may be relatively reduced. For example, even if at least some of the first to third circuit connection portions CPa, CPb, and CPc overlap the first to third emission areas EAa, EAb, and EAc, the second electrodes may be easily electrically connected to the first to third pixel driving circuits PCa, PCb, and PCc through the first to third connection electrodes CEa, CEb, and CEc and the first to third connection patterns CNPa, CNPb, and CNPc, respectively. Accordingly, shapes, arrangements, or the like, of the first to third pixel driving circuits PCa, PCb, and PCc may be designed independently of the positions, shapes, and sizes of the first to third emission areas EAa, EAb, and EAc. Accordingly, a degree of design freedom of each of the first to third pixel driving circuits PCa, PCb, and PCc may be relatively improved.

According to some embodiments, the first to third pixel driving circuits PCa, PCb, and PCc may be designed to be the same as each other regardless of the positions, shapes, and sizes of the first to third emission areas EAa, EAb, and EAc. In addition, as described above, the position of the first circuit connection portion CPa may correspond to the position of the first transistor of the first pixel driving circuit PCa, the position of the second circuit connection portion CPb may correspond to the position of the first transistor of the second pixel driving circuit PCb, and the position of the third circuit connection portion CPc may correspond to the position of the first transistor of the third pixel driving circuit PCc. Accordingly, when the first to third pixel driving circuits PCa, PCb, and PCc are formed to have the same (or substantially the same) size and to be located along the first direction DR1, the position of the first circuit connection portion CPa, the position of the second circuit connection portion CPb, and the position of the third circuit connection portion CPc may be arranged along the first direction DR1.

As illustrated in FIG. 3, the shape or arrangement of each of the first to third connection electrodes CEa, CEb, and CEc and the arrangement relationship between the first to third connection electrodes CEa, CEb, and CEc may be the same for each first unit emission area UEA1. In addition, the shape or arrangement of each of the first to third connection electrodes CEa, CEb, and CEc and the arrangement relationship between the first to third connection electrodes CEa, CEb, and CEc may be the same for each second unit emission area UEA2.

In addition, the shape or arrangement of each of the first to third connection patterns CNPa, CNPb, and CNPc and the arrangement relationship between the first to third connection patterns CNPa, CNPb, and CNPc may be the same for each first unit emission area UEA1. In addition, the shape or arrangement of each of the first to third connection patterns CNPa, CNPb, and CNPc and the arrangement relationship between the first to third connection patterns CNPa, CNPb, and CNPc may be the same for each second unit emission area UEA2.

In addition, the shape or arrangement of each of the first to third additional connection patterns ADPa, ADPb, and ADPc and the arrangement relationship between the first to third additional connection patterns ADPa, ADPb, and ADPc may be the same for each first unit emission area UEA1. In addition, the shape or arrangement of each of the first to third additional connection patterns ADPa, ADPb, and ADPc and the arrangement relationship between the first to third additional connection patterns ADPa, ADPb, and ADPc may be the same for each second unit emission area UEA2.

As described above, the display device DD may include the separator SPR. The separator SPR may be located on the pixel defining layer PDL the first to third connection patterns CNPa, CNPb, and CNPc, and the first to third additional connection patterns ADPa, ADPb, and ADPc. According to some embodiments, the separator SPR may include an organic insulating material. For example, the separator SPR may include a photosensitive resin (e.g., a photoresist). However, embodiments according to the present disclosure are not limited thereto.

The separator SPR may be located between the first to third emission areas EAa, EAb, and EAc in a plan view. For example, the separator SPR may be located between the first emission area EAa and the second emission area EAb, between the second emission area EAb and the third emission area EAc, and between the first emission area EAa and the third emission area EAc in a plan view. According to some embodiments, the separator SPR may entirely surround the first to third emission areas EAa, EAb, and EAc in a plan view.

The separator SPR may overlap the first to third connection patterns CNPa, CNPb, and CNPc in a plan view. In addition, the separator SPR may entirely surround the first to third connection patterns CNPa, CNPb, and CNPc in a plan view. For example, the separator SPR may cover a portion of each of the first to third connection patterns CNPa, CNPb, and CNPc and an area between adjacent connection patterns. That is, at least a portion of the separator SPR may extend along an edge of each of the first to third connection patterns CNPa, CNPb, and CNPc in a plan view. Accordingly, areas where the second electrodes and the first to third connection patterns CNPa, CNPb, and CNPc contact each other may be adjacent to or overlap the separator SPR in a plan view.

The separator SPR may be located between the first to third additional connection patterns ADPa, ADPb, and ADPc in a plan view. For example, the separator SPR may be located between the first additional connection pattern ADPa and the second additional connection pattern ADPb, between the second additional connection pattern ADPb and the third additional connection pattern ADPc, and between the first additional connection pattern ADPa and the third additional connection pattern ADPc in a plan view. According to some embodiments, the separator SPR may entirely surround the first to third additional connection patterns ADPa, ADPb, and ADPc in a plan view.

The separator SPR may separate (or, disconnect) the electrode layer (E2L, see FIG. 5) into the second electrode of the first light emitting element LDa, the second electrode of the second light emitting element LDb, and the second electrode of the third light emitting element LDc. Thus, the second electrode of the first light emitting element LDa, the second electrode of the second light emitting element LDb, and the second electrode of the third light emitting element LDc may be spaced apart from each other. In addition, the second electrode of the first light emitting element LDa, the second electrode of the second light emitting element LDb, and the second electrode of the third light emitting element LDc may be electrically independent of each other.

The separator SPR may define first to third open areas OA1, OA2, and OA3 respectively corresponding to the second electrodes. For example, the separator SPR may have a mesh structure surrounding the second electrodes in a plan view. The second electrode of the first light emitting element LDa may be located in the first open area OA1 of the separator SPR, the second electrode of the second light emitting element LDb may be located in the second open area OA2 of the separator SPR, and the second electrode of the third light emitting element LDc may be located in the third open area OA3 of the separator SPR.

According to some embodiments, a planar shape of the first open area OA1 may be the same (or substantially the same) as a planar shape of the second electrode of the first light emitting element LDa, a planar shape of the second open area OA2 may be the same (or substantially the same) as a planar shape of the second electrode of the second light emitting element LDb, and a planar shape of the third open area OA3 may be the same (or substantially the same) as a planar shape of the second electrode of the third light emitting element LDc.

The first to third open areas OA1, OA2, and OA3 of the separator SPR may correspond to the first to third connection patterns CNPa, CNPb, and CNPc, respectively. For example, the first connection pattern CNPa may overlap the first open area OA1, the second connection pattern CNPb may overlap the second open area OA2, and the third connection pattern CNPc may overlap the third open area OA3.

In addition, the first to third open areas OA1, OA2, and OA3 of the separator SPR may correspond to the first to third additional connection patterns ADPa, ADPb, and ADPc, respectively. For example, the first additional connection pattern ADPa may overlap the first open area OA1, the second additional connection pattern ADPb may overlap the second open area OA2, and the third additional connection pattern ADPc may overlap the third open area OA3.

Hereinafter, the cross-sectional structure of the display device DD will be described in more detail with reference to FIGS. 5 and 6, focusing on the first emission area EAa. The following description of the cross-sectional structure of the display device DD may be equally (or substantially equally) applied to all emission areas.

Referring further to FIGS. 5 and 6, the display device DD may include the substrate SUB, a first bottom conductive layer BML1, a second bottom conductive layer BML2, the first transistor TR1, the second transistor TR2, the first capacitor CAP1, the second capacitor CAP2, the first connection electrode CEa, first to sixth insulating layers IL1, IL2, IL3, IL4, IL5, and IL6, the pixel defining layer PDL, the first and second connection patterns CNPa and CNPb, the first and second additional connection patterns ADPa and ADPb, the first light emitting element LDa, the separator SPR, a first dummy layer DP1, a second dummy layer DP2, and an encapsulation layer ENC.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include the first capacitor electrode CPE1 and a third capacitor electrode CPE3. The first light emitting element LDa may include the first electrode E1, the intermediate layer ML, and the second electrode E2.

As described above, the first transistor TR1, the second transistor TR2, the first capacitor CAP1, and the second capacitor CAP2 may be components included in the first pixel driving circuit PCa.

The substrate SUB may serve as a base of the display device DD. According to some embodiments, examples of materials that may be used as the substrate SUB may include glass, quartz, silicon, polymers, or the like. These may be used alone or in combination with each other. In addition, the substrate SUB may have a single-layer structure or a multi-layer structure in which a plurality of layers including different materials are stacked.

The first bottom conductive layer BML1, the second bottom conductive layer BML2, and the third capacitor electrode CPE3 may be located on the substrate SUB. The first bottom conductive layer BML1, the second bottom conductive layer BML2, and the third capacitor electrode CPE3 may include a conductive material such as a metal, an alloy, a conductive metal oxide, a conductive metal nitride, a transparent conductive oxide, or the like.

The first insulating layer IL1 may cover the first bottom conductive layer BML1, the second bottom conductive layer BML2, and the third capacitor electrode CPE3 and may be located on the substrate SUB. The first insulating layer IL1 may prevent or reduce metal atoms or impurities from diffusing from the substrate SUB to the first active pattern AP1 and/or the second active pattern AP2. The first insulating layer IL1 may include an insulating material. Examples of the insulating material that may be used as the first insulating layer IL1 may include silicon oxide (SiOₓ), silicon nitride (SiNₓ), silicon oxynitride (SiOₓN_{y}), or the like. These may be used alone or in combination with each other.

The first active pattern AP1 may be located on the first insulating layer IL1. According to some embodiments, the first active pattern AP1 may overlap the first bottom conductive layer BML1. The first active pattern AP1 may include an oxide semiconductor material, a silicon semiconductor material, and/or an organic semiconductor material. The first active pattern AP1 may include a first contact area S1, a second contact area D1, and a first channel area CH1 between the first contact area S1 and the second contact area D1. The first contact area S1 and the second contact area D1 may have higher conductivity than the first channel area CH1.

The second active pattern AP2 may be located on the first insulating layer IL1. According to some embodiments, the second active pattern AP2 may overlap the second bottom conductive layer BML2. The second active pattern AP2 may include an oxide semiconductor material, a silicon semiconductor material, and/or an organic semiconductor material. The second active pattern AP2 may include a third contact area S2, a fourth contact area D2, and a second channel area CH2 between the third contact area S2 and the fourth contact area D2. The third contact area S2 and the fourth contact area D2 may have higher conductivity than the second channel area CH2.

According to some embodiments, the first active pattern AP1 and the second active pattern AP2 may include an oxide semiconductor material. Examples of the oxide semiconductor material that may be used as the first active pattern AP1 and the second active pattern AP2 may include indium gallium zinc oxide (IGZO), zinc tin oxide (ZTO), indium tin zinc oxide (ITZO), or the like. These may be used alone or in combination with each other. However, embodiments according to the present disclosure are not limited thereto, and the first active pattern AP1 and the second active pattern AP2 may include different materials from each other. For example, one of the first active pattern AP1 and the second active pattern AP2 may include an oxide semiconductor material, and the other may include a silicon semiconductor material.

FIG. 5 illustrates that the first active pattern AP1 and the second active pattern AP2 are located in the same layer as each other. However, embodiments according to the present disclosure are not limited thereto, and the first active pattern AP1 and the second active pattern AP2 may be located in different layers from each other.

The second insulating layer IL2 may cover the first active pattern AP1 and the second active pattern AP2 and may be located on the first insulating layer IL1. The second insulating layer IL2 may include an insulating material. Examples of the insulating material that may be used as the second insulating layer IL2 may include silicon oxide (SiOₓ), silicon nitride (SiNₓ), silicon oxynitride (SiOₓN_{y}), or the like. These may be used alone or in combination with each other.

The first gate electrode GE1 may be located on the second insulating layer IL2. The first gate electrode GE1 may overlap the first channel area CH1 of the first active pattern AP1. The first gate electrode GE1 may include a conductive material such as a metal, an alloy, a conductive metal oxide, a conductive metal nitride, a transparent conductive oxide, or the like. According to some embodiments, the first gate electrode GE1 may contact the first bottom conductive layer BML1.

The second gate electrode GE2 may be located on the second insulating layer IL2. The second gate electrode GE2 may overlap the second channel area CH2 of the second active pattern AP2. The second gate electrode GE2 may include a conductive material such as a metal, an alloy, a conductive metal oxide, a conductive metal nitride, a transparent conductive oxide, or the like. According to some embodiments, the second gate electrode GE2 may contact the second bottom conductive layer BML2.

The first capacitor electrode CPE1 may be located on the second insulating layer IL2. The first capacitor electrode CPE1 may overlap the third capacitor electrode CPE3 in a plan view. The first capacitor electrode CPE1 and the third capacitor electrode CPE3 may form the second capacitor CAP2. The first capacitor electrode CPE1 may include a conductive material such as a metal, an alloy, a conductive metal oxide, a conductive metal nitride, a transparent conductive oxide, or the like.

The third insulating layer IL3 may cover the first gate electrode GE1, the second gate electrode GE2, and the first capacitor electrode CPE1 and may be located on the second insulating layer IL2. The third insulating layer IL3 may include an insulating material. Examples of the insulating material that may be used as the third insulating layer IL3 may include silicon oxide (SiOₓ), silicon nitride (SiNₓ), silicon oxynitride (SiOₓN_{y}), or the like. These may be used alone or in combination with each other.

The second capacitor electrode CPE2 may be located on the third insulating layer IL3. The second capacitor electrode CPE2 may overlap the first capacitor electrode CPE1 in a plan view. The first capacitor electrode CPE1 and the second capacitor electrode CPE2 may form the first capacitor CAP1. The second capacitor electrode CPE2 may include a conductive material such as a metal, an alloy, a conductive metal oxide, a conductive metal nitride, a transparent conductive oxide, or the like.

The fourth insulating layer IL4 may cover the second capacitor electrode CPE2 and may be located on the third insulating layer IL3. The fourth insulating layer IL4 may include an insulating material. Examples of the insulating material that may be used as the fourth insulating layer IL4 may include silicon oxide (SiOₓ), silicon nitride (SiNₓ), silicon oxynitride (SiOₓN_{y}), or the like. These may be used alone or in combination with each other.

The first to fourth contact electrodes SE1, DE1, SE2, and DE2 may be located on the fourth insulating layer IL4. The first contact electrode SE1 may contact the first contact area S1 of the first active pattern AP1, the second contact electrode DE1 may contact the second contact area D1 of the first active pattern AP1, the third contact electrode SE2 may contact the third contact area S2 of the second active pattern AP2, and the fourth contact electrode DE2 may contact the fourth contact area D2 of the second active pattern AP2. The first to fourth contact electrodes SE1, DE1, SE2, and DE2 may include a conductive material such as a metal, an alloy, a conductive metal oxide, a conductive metal nitride, a transparent conductive oxide, or the like.

According to some embodiments, the first contact electrode SE1 may contact the first bottom conductive layer BML1, and the third contact electrode SE2 may contact the second bottom conductive layer BML2. However, embodiments according to the present disclosure are not limited thereto. For example, when the first gate electrode GE1 contacts the first bottom conductive layer BML1, the first contact electrode SE1 may not contact the first bottom conductive layer BML1. In addition, when the second gate electrode GE2 contacts the second bottom conductive layer BML2, the third contact electrode SE2 may not contact the second bottom conductive layer BML2.

Accordingly, the first transistor TR1 including the first active pattern AP1, the first gate electrode GE1, the first contact electrode SE1, and the second contact electrode DE1 may be formed. As described above, the first transistor TR1 may be a transistor that is connected to the light emitting element through the connection electrode and the connection pattern. For example, when the first pixel driving circuit PCa is the pixel driving circuit PC of FIG. 2A, the first transistor TR1 may be the first transistor T1 of FIG. 2A. In addition, when the first pixel driving circuit PCa is the pixel driving circuit PC′ of FIG. 2B, the first transistor TR1 may be the fifth transistor T5 of FIG. 2B. In addition, when the first pixel driving circuit PCa is the pixel driving circuit PC″ of FIG. 2C, the first transistor TR1 may be the fifth transistor T5 of FIG. 2C.

In addition, the second transistor TR2 including the second active pattern AP2, the second gate electrode GE2, the third contact electrode SE2, and the fourth contact electrode DE2 may be formed. For example, when the first pixel driving circuit PCa is the pixel driving circuit PC of FIG. 2A, the second transistor TR2 may be the second transistor T2 of FIG. 2A. In addition, when the first pixel driving circuit PCa is the pixel driving circuit PC′ of FIG. 2B, the second transistor TR2 may be any one of the first to fourth transistors T1, T2, T3, and T4 and the sixth transistor T6 of FIG. 2B. In addition, when the first pixel driving circuit PCa is the pixel driving circuit PC″ of FIG. 20, the second transistor TR2 may be any one of the first to fourth transistors T1′, T2, T3, and T4 and the sixth to eighth transistors T6, T7, and T8 of FIG. 2C.

The fifth insulating layer IL5 may cover the first to fourth contact electrodes SE1, DE1, SE2, and DE2 and may be located on the fourth insulating layer IL4. The fifth insulating layer IL5 may include an insulating material. For example, the fifth insulating layer IL5 may include an organic insulating material. Examples of the organic insulating material that may be used as the fifth insulating layer IL5 may include photoresist, polyacryl-based resin, polyimide-based resin, polyamide-based resin, siloxane-based resin, acrylic-based resin, epoxy-based resin, or the like. These may be used alone or in combination with each other.

The first connection electrode CEa may be located on the fifth insulating layer IL5. As described above, the first connection electrode CEa may be connected to the first transistor TR1. For example, the first connection electrode CEa may contact the first transistor TR1 through a contact hole CNT that penetrates the fifth insulating layer IL5. Accordingly, the position of the first circuit connection portion CPa may correspond to a position of the contact hole CNT. The first connection electrode CEa may include a conductive material such as a metal, an alloy, a conductive metal oxide, a conductive metal nitride, a transparent conductive oxide, or the like. According to some embodiments, the first connection electrode CEa may have a single-layer structure or a multi-layer structure in which a plurality of conductive layers are stacked.

The sixth insulating layer IL6 may partially cover the first connection electrode CEa and may be located on the fifth insulating layer IL5. That is, the sixth insulating layer IL6 may define a first sub-opening SO1 that exposes at least a portion of the first connection electrode CEa. The sixth insulating layer IL6 may include an insulating material. For example, the sixth insulating layer IL6 may include an organic insulating material. Examples of the organic insulating material that may be used as the sixth insulating layer IL6 may include photoresist, polyacryl-based resin, polyimide-based resin, polyamide-based resin, siloxane-based resin, acrylic-based resin, epoxy-based resin, or the like. These may be used alone or in combination with each other.

The first electrode E1 may be located on the first connection electrode CEa. For example, the first electrode E1 may be located on the sixth insulating layer IL6. The first electrode E1 may include a conductive material such as a metal, an alloy, a conductive metal oxide, a conductive metal nitride, a transparent conductive oxide, or the like. As described above, the first electrode E1 may function as the anode of FIGS. 2A, 2B, and 2C.

The pixel defining layer PDL may be located on the sixth insulating layer IL6 and the first electrode E1. The pixel defining layer PDL may define a pixel opening that exposes at least a portion of the first electrode E1. The first emission area EAa may be defined by the pixel opening. The pixel defining layer PDL may include an insulating material. For example, the pixel defining layer PDL may include an organic insulating material.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. That is, the first sub-opening SO1 and the second sub-opening SO2 may be connected to define an opening OP, and the opening OP may expose at least a portion of the first connection electrode CEa.

The first connection pattern CNPa may be located on the first connection electrode CEa, the sixth insulating layer IL6, and the pixel defining layer PDL. As described above, the first connection pattern CNPa may be electrically connected to the first connection electrode CEa. For example, the first connection pattern CNPa may be connected to the first connection electrode CEa through the opening OP that penetrates the sixth insulating layer IL6 and the pixel defining layer PDL. Accordingly, the position of the first light emitting connection portion CNa may correspond to a position of the opening OP.

According to some embodiments, the first connection pattern CNPa may include a transparent conductive oxide. However, embodiments according to the present disclosure are not limited thereto, and the first connection pattern CNPa may include a conductive material such as a metal, an alloy, a conductive metal nitride, or the like. According to some embodiments, the first connection pattern CNPa may have a single-layer structure or a multi-layer structure in which a plurality of conductive layers are stacked.

The separator SPR may be located on the pixel defining layer PDL and the first connection pattern CNPa. The separator SPR may overlap the first connection pattern CNPa in a plan view. The separator SPR may cover a portion of the first connection pattern CNPa and a portion of the connection pattern adjacent to the first connection pattern CNPa. For example, as illustrated in FIG. 5, the separator SPR may cover a portion of the first connection pattern CNPa and a portion of the second connection pattern CNPb adjacent to the first connection pattern CNPa. In this case, one of a first side surface and a second side surface opposite to the first side surface of the separator SPR may contact the first connection pattern CNPa, and the other may contact the second connection pattern CNPb.

A width of an upper portion of the separator SPR may be greater than a width of a lower portion of the separator SPR. That is, the side surface of the separator SPR connecting an upper surface of the separator SPR to a lower surface of the separator SPR may have a reverse tapered slope. In other words, a cross-section of at least a portion of the separator SPR may be reverse trapezoid.

According to some embodiments, as illustrated in FIG. 5, the side surface of the separator SPR may have a plurality of reverse tapered slopes. That is, the separator SPR may have a double reverse tapered structure. Thus, the separation (or, disconnection) of the electrode layer E2L by the separator SPR may be more easily implemented.

The first additional connection pattern ADPa may be located on the pixel defining layer PDL. The first additional connection pattern ADPa may extend from the first connection pattern CNPa. For example, in a cross-section, the first additional connection pattern ADPa may extend from the first connection pattern CNPa in a direction away from a central portion of the separator SPR. The first additional connection pattern ADPa may be spaced apart from the first electrode E1. The first additional connection pattern ADPa and the first electrode E1 may be electrically independent of each other.

According to some embodiments, the first additional connection pattern ADPa may include the same material as the first connection pattern CNPa and may be formed integrally with the first connection pattern CNPa.

According to some embodiments, the first additional connection pattern ADPa may include a transparent conductive oxide. However, embodiments according to the present disclosure are not limited thereto, and the first additional connection pattern ADPa may include a conductive material such as a metal, alloy, conductive metal nitride, or the like. According to some embodiments, the first additional connection pattern ADPa may have a single-layer structure or a multi-layer structure in which a plurality of conductive layers are stacked.

A width of each of the connection patterns CNPa, CNPb, and CNPc may be formed to account for a deviation in the process of forming the separator SPR. For example, the width of each of the connection patterns CNPa, CNPb, and CNPc may be formed to account for an alignment error of a mask used in the process for forming the separator SPR. According to some embodiments, the width of each of the connection patterns CNPa, CNPb, and CNPc may be greater than or equal to 2 micrometers (or about 2 micrometers) and less than or equal to 4 micrometers (or about 4 micrometers). For example, as illustrated in FIG. 6, a first width WD1 (e.g., a length in the second direction DR2) of each of the first connection pattern CNPa and the second connection pattern CNPb may be greater than or equal to 2 micrometers (or about 2 micrometers) and less than or equal to 4 micrometers (or about 4 micrometers).

A width of each of the additional connection patterns ADPa, ADPb, and ADPc may be formed to account for a deviation in the process of forming the separator SPR. For example, the width of each of the additional connection patterns ADPa, ADPb, and ADPc may be formed to account for the process distribution of a double reverse tapered structure formed on the side surface of the separator SPR.

As illustrated in FIG. 6, the plurality of reverse tapered slopes on the side surface of the separator SPR may include a first reverse tapered slope TP1 and a second reverse tapered slope TP2. The first reverse tapered slope TP1 may be connected to the upper surface of the separator SPR and the second reverse tapered slope TP2. The second reverse tapered slope TP2 may be connected to the first reverse tapered slope TP1, and may contact the first connection pattern CNPa or the second connection pattern CNPb. Here, a first skew SK1 may be defined as an in-plane distance (e.g., a distance in the second direction DR2) between an end of the upper surface of the separator SPR and a portion where the first reverse tapered slope TP1 and the second reverse tapered slope TP2 meet. In addition, a second skew SK2 may be defined as an in-plane distance (e.g., a distance in the second direction DR2) between the end of the upper surface of the separator SPR and a portion where the second reverse tapered slope TP2 contacts the first connection pattern CNPa or the second connection pattern CNPb.

According to some embodiments, the width of each of the additional connection patterns ADPa, ADPb, and ADPc may be greater than or equal to 0.3 micrometers (or about 0.3 micrometers) and less than or equal to 3 micrometers (or about 3 micrometers). For example, as illustrated in FIG. 6, a second width WD2 (e.g., a length in the second direction DR2) of each of the first additional connection pattern ADPa and the second additional connection pattern ADPb may be greater than or equal to 0.3 micrometers (or about 0.3 micrometers) and less than or equal to 3 micrometers (or about 3 micrometers).

The width of each of the additional connection patterns ADPa, ADPb, and ADPc may be formed to account for a difference SK2-SK1 between the second skew SK2 and the first skew SK1. For example, the width of each of the additional connection patterns ADPa, ADPb, and ADPc may be formed to account for the distribution of the difference SK2-SK1 between the second skew SK2 and the first skew SK1 that occurs in the process of forming the double reverse tapered structure. For example, when a target difference value between the second skew SK2 and the first skew SK1 is 0.5 micrometers (or about 0.5 micrometers), the width of each of the additional connection patterns ADPa, ADPb, and ADPc may be 0.3 micrometers (or about 0.3 micrometers). In this case, when the width of each of the additional connection patterns ADPa, ADPb, and ADPc is less than 0.3 micrometers (or about 0.3 micrometers), when the distribution of the difference SK2-SK1 between the second skew SK2 and the first skew SK1 occurs in the process of forming the double reverse tapered structure, the double reverse tapered structure may not be smoothly formed on the side surface of the separator SPR. However, embodiments according to the present disclosure are not limited thereto, and a minimum value of the width of each of the additional connection patterns ADPa, ADPb, and ADPc may be different depending on the target difference value between the second skew SK2 and the first skew SK1.

In addition, a maximum value of the width of each of the additional connection patterns ADPa, ADPb, and ADPc may be determined to account for an in-plane distance between the first electrode E1 and the corresponding connection pattern.

That is, because each of the additional connection patterns ADPa, ADPb, and ADPc may be electrically independent of the first electrode E1, the maximum value of the width of each of the additional connection patterns ADPa, ADPb, and ADPc may be determined to account for the in-plane distance between the first electrode E1 and the corresponding connection pattern. For example, as illustrated in FIG. 6, the maximum value of the second width WD2 of the first additional connection pattern ADPa may be determined to account for the in-plane distance between the first electrode E1 and the first connection pattern CNPa.

The intermediate layer ML may be located on the first electrode E1, the pixel defining layer PDL, the first connection pattern CNPa, and the first additional connection pattern ADPa. A portion of the intermediate layer ML may be located within the pixel opening of the pixel defining layer PDL. According to some embodiments, the intermediate layer ML may include a first functional layer including an organic material, an emission layer located on the first functional layer and including an emission material, and a second functional layer located on the emission layer and including an organic material. For example, the first functional layer may include a hole injection layer, a hole transport layer, or the like, and the second functional layer may include an electron transport layer, an electron injection layer, or the like.

A shadow area where it is difficult to deposit the intermediate layer ML may exist around the separator SPR having the reverse tapered slope. Accordingly, in the shadow area and/or around the shadow area, the intermediate layer ML may have a structure separated (or disconnected) by the separator SPR. Because the intermediate layer ML has a separated (or disconnected) structure, the intermediate layer ML may expose a portion of the first connection pattern CNPa at a position adjacent to or overlapping the separator SPR. Accordingly, the second electrode E2 of the first light emitting element LDa may contact the first connection pattern CNPa.

The first dummy layer DP1 may be located on the separator SPR. The first dummy layer DP1 may be formed because the intermediate layer ML has a structure separated (or disconnected) by the separator SPR. That is, the first dummy layer DP1 may be formed in the same process as the intermediate layer ML. According to some embodiments, the first dummy layer DP1 may be omitted.

The electrode layer E2L may be located on the first electrode E1. For example, the electrode layer E2L may be located on the intermediate layer ML. The electrode layer E2L may include a conductive material, such as a metal, an alloy, a conductive metal oxide, a conductive metal nitride, a transparent conductive material, or the like. As described above, the electrode layer E2L may function as the cathode of FIGS. 2A, 2B, and 2C.

According to some embodiments, the electrode layer E2L may have a single-layer structure. However, embodiments according to the present disclosure are not limited thereto, and the electrode layer E2L may have a multi-layer structure in which a plurality of conductive layers are stacked. For example, the electrode layer E2L may have a two-layer structure including a first sub-electrode layer including a metal and a second sub-electrode layer located on the first sub-electrode layer and including a transparent conductive oxide.

The shadow area where it is difficult to deposit the electrode layer E2L may exist around the separator SPR having the reverse tapered slope. In the shadow area and/or around the shadow area, the electrode layer E2L may have a structure separated (or disconnected) by the separator SPR. For example, the electrode layer E2L may be separated (or disconnected) into the second electrode E2 of the first light emitting element LDa, the second electrode of the second light emitting element LDb, and the second electrode of the third light emitting element LDc. That is, the second electrode E2 of the first light emitting element LDa, the second electrode of the second light emitting element LDb, and the second electrode of the third light emitting element LDc may be electrically insulated from each other.

As illustrated in FIG. 5, the electrode layer E2L (for example, the second electrode E2) may be electrically connected to the first connection pattern CNPa. For example, the electrode layer E2L (for example, the second electrode E2) may contact the first connection pattern CNPa at a position adjacent to or overlapping the separator SPR. For example, when a deposition angle of a deposition process for forming the electrode layer E2L is greater than a deposition angle of a deposition process for forming the intermediate layer ML, the electrode layer E2L (for example, the second electrode E2) may be formed to cover a side portion of the separated (or disconnected) intermediate layer ML and to contact the first connection pattern CNPa. As a result, the second electrode E2 may be electrically connected to the first transistor TR1 through the first connection electrode CEa and the first connection pattern CNPa.

The second dummy layer DP2 may be located on the separator SPR. For example, the second dummy layer DP2 may be located on the first dummy layer DP1. The second dummy layer DP2 may be formed because the electrode layer E2L has a structure separated (or disconnected) by the separator SPR. That is, the second dummy layer DP2 may be formed in the same process as the electrode layer E2L. According to some embodiments, the second dummy layer DP2 may be omitted.

The encapsulation layer ENC may be located on the electrode layer E2L. The encapsulation layer ENC may entirely cover the electrode layer E2L, the connection patterns CNPa, CNPb, and CNPc, the separator SPR, the first dummy layer DP1, and the second dummy layer DP2. According to some embodiments, the encapsulation layer ENC may include a first inorganic encapsulation layer IEL1 including an inorganic insulating material, an organic encapsulation layer OEL located on the first inorganic encapsulation layer IEL1 and including an organic insulating material, and a second inorganic encapsulation layer IEL2 located on the organic encapsulation layer OEL and including an inorganic insulating material.

According to some embodiments, a touch sensing layer may be located on the encapsulation layer ENC. For example, the touch sensing layer may include a plurality of touch electrode arrays for detecting a user's handling in a capacitive manner, a touch pad portion, and a plurality of touch lines electrically connecting the touch pad portion and the touch electrode arrays. However, embodiments according to the present disclosure are not limited thereto. According to some embodiments, the touch sensing layer may be omitted.

According to some embodiments, the display device DD may include the connection electrodes CEa, CEb, and CEc, the connection patterns CNPa, CNPb, and CNPc, and the separator SPR. Accordingly, the electrode layer E2L (e.g., the cathode) located on the first electrode E1 (e.g., the anode) may be easily connected to the pixel driving circuits PCa, PCb, and PCc. For example, the electrode layer E2L located on the first electrode E1 may be connected to a drain of the driving transistor (e.g., the first transistor T1 (or T1) of FIGS. 2A, 2B, and 2C) of each of the pixel driving circuits PCa, PCb, and PCc through the connection electrodes CEa, CEb, and CEc and the connection patterns CNPa, CNPb, and CNPc. Accordingly, even when the light emitting element deteriorates, the gate-source voltage (Vgs) of the driving transistor may not change. Accordingly, the range of change in the driving current due to the deterioration of the light emitting element may be relatively reduced. Therefore, the after-image defect of the display device DD depending on an increase in the time of use may be relatively reduced, and the lifespan of the display device DD may be relatively improved.

In addition, according to some embodiments, the display device DD may include the additional connection patterns ADPa, ADPb, and ADPc extending from the connection patterns CNPa, CNPb, and CNPc, respectively. The width of each of the additional connection patterns ADPa, ADPb, and ADPc may be formed to account for the deviation in the process of forming the separator SPR. For example, the width of each of the additional connection patterns ADPa, ADPb, and ADPc may be formed to account for the process distribution of the double reverse tapered structure formed on the side surface of the separator SPR. As the display device DD includes the additional connection patterns ADPa, ADPb, and ADPc extending from the connection patterns CNPa, CNPb, and CNPc, respectively, the double reverse tapered structure may be smoothly formed on the side surface of the separator SPR even if the distribution occurs in the process of forming the double reverse tapered structure.

Accordingly, separation (or, disconnection) of the electrode layer E2L by the separator SPR may be more easily implemented.

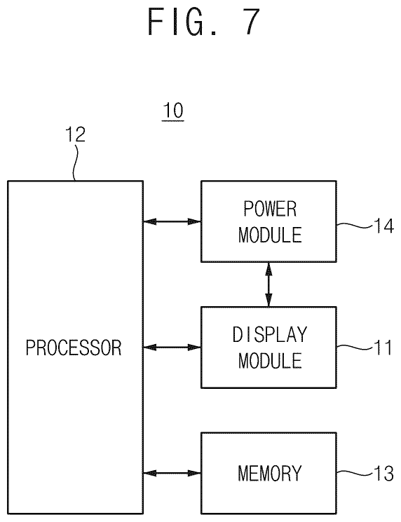

FIG. 7 is a block diagram of an electronic device according to some embodiments of the present disclosure.

Referring to FIG. 7, an electronic device 10 according to some embodiments may include a display module 11, a processor 12, a memory 13, and a power module 14. The display device according to some embodiments may be applied to a variety of electronic devices. The electronic device 10 according to some embodiments may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

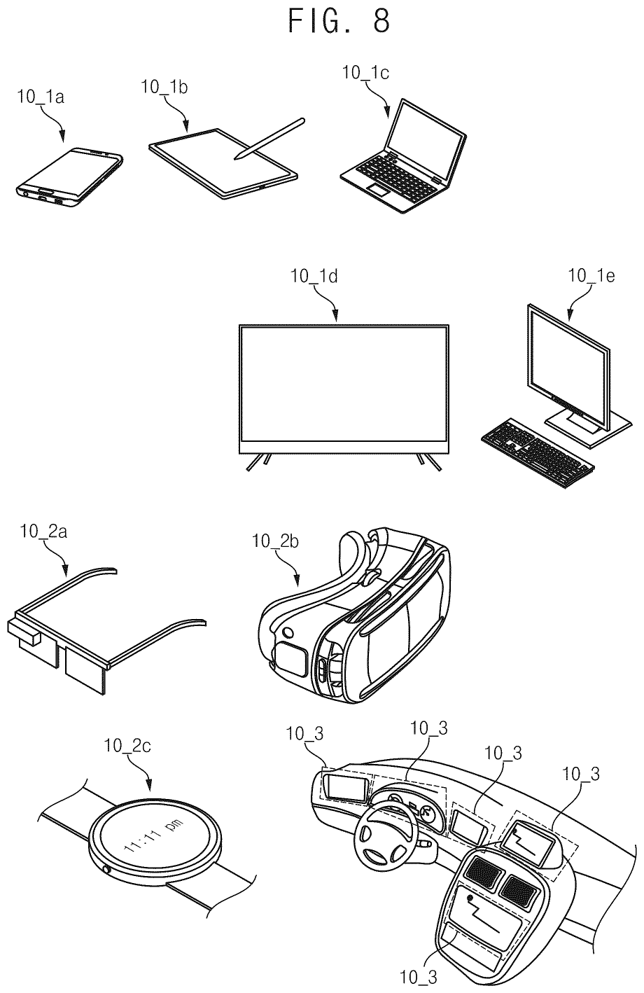

FIG. 8 is a schematic diagram of an electronic device according to various embodiments.

Referring to FIG. 8, various electronic devices to which a display device according to the embodiments is applied may include image display electronic devices such as a smartphones 10_1a, a tablet PC 10_1b, a laptop 10_1c, a television 10_1d, a desk monitor 10_1e, etc., wearable electronic devices including display modules such as a smart glasses 10_2a, a head-mounted display 10_2b, and a smart watch 10_2c, etc., and vehicle electronic devices 10_3 including display modules such as a CID (center information display) which may be located on, for example, an instrument panel, a center fascia, and a dashboard of an automobile and a room mirror display, etc.

Aspects of some embodiments of the present disclosure may be applied to various display devices. For example, embodiments according to the present disclosure are applicable to various display devices such as display devices for vehicles, ships and aircraft, portable communication devices, display devices for exhibition or information transmission, medical display devices, and the like.

The foregoing is illustrative of aspects of some embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the claims, and their equivalents.

What is claimed is:

1. A display device comprising:
a pixel driving circuit comprising a transistor;
a connection electrode electrically connected to the pixel driving circuit;
a first electrode on the connection electrode;
a pixel defining layer defining an opening exposing a portion of the first electrode;
a connection pattern on the connection electrode and the pixel defining layer and electrically connected to the connection electrode;
an electrode layer on the first electrode and electrically connected to the connection pattern;
a separator on the pixel defining layer and the connection pattern, separating the electrode layer into a plurality of second electrodes spaced apart from each other, and covering at least a portion of the connection pattern; and
an additional connection pattern on the pixel defining layer and extending from the connection pattern in a direction away from a central portion of the separator in a cross-section.

2. The display device of claim 1, wherein a side surface of the separator contacts the connection pattern and has a plurality of reverse tapered slopes in the cross-section.

3. The display device of claim 2,
wherein the plurality of reverse tapered slopes comprise a first reverse tapered slope and a second reverse tapered slope,
wherein the first reverse tapered slope is connected to an upper surface of the separator, and
wherein the second reverse tapered slope contacts the connection pattern.

4. The display device of claim 1, wherein the additional connection pattern comprises a same material as the connection pattern.

5. The display device of claim 1, wherein the additional connection pattern comprises a transparent conductive oxide.

6. The display device of claim 1, wherein a width of the additional connection pattern is greater than or equal to 0.3 micrometers and less than or equal to 3 micrometers.

7. The display device of claim 1, wherein a width of the connection pattern is greater than or equal to 2 micrometers and less than or equal to 4 micrometers.

8. The display device of claim 1, wherein the additional connection pattern and the first electrode are electrically independent of each other.

9. The display device of claim 1, wherein each of the plurality of second electrodes is electrically connected to the pixel driving circuit through the connection pattern and the connection electrode.

10. The display device of claim 1, wherein each of the plurality of second electrodes contacts the connection pattern at a position adjacent to or overlapping the separator.

11. The display device of claim 1, further comprising:
an intermediate layer between the first electrode and the electrode layer and comprising an emission material.

12. A display device comprising:
a pixel driving circuit comprising a transistor;
a connection electrode electrically connected to the pixel driving circuit;
a first electrode on the connection electrode;
a pixel defining layer covering a portion of the first electrode and defining an emission area;
a connection pattern electrically connected to the connection electrode and surrounding at least a portion of the emission area in a plan view;
an electrode layer on the first electrode and electrically connected to the connection pattern;
a separator on the pixel defining layer and the connection pattern, separating the electrode layer into a plurality of second electrodes spaced apart from each other, and overlapping the connection pattern in the plan view; and
an additional connection pattern extending from the connection pattern and between the connection pattern and the emission area in the plan view.

13. The display device of claim 12, wherein the additional connection pattern surrounds at least a portion of the emission area in the plan view.

14. The display device of claim 12, wherein the connection pattern surrounds at least a portion of the additional connection pattern in the plan view.

15. The display device of claim 12, wherein the separator entirely surrounds the connection pattern and the additional connection pattern in the plan view.

16. The display device of claim 12, wherein a side surface of the separator contacts the connection pattern and has a plurality of reverse tapered slopes in a cross-section.

17. The display device of claim 12, wherein the additional connection pattern comprises a same material as the connection pattern.

18. The display device of claim 12, wherein a width of the additional connection pattern is greater than or equal to 0.3 micrometers and less than or equal to 3 micrometers.

19. The display device of claim 12, wherein the additional connection pattern and the first electrode are electrically independent of each other.

20. An electronic device comprising:
a display device comprising a pixel; and
a processor configured to transmit an image data signal and an input control signal to the display device,
wherein the display device comprises:
a pixel driving circuit comprising a transistor;
a connection electrode electrically connected to the pixel driving circuit;
a first electrode on the connection electrode;
a pixel defining layer defining an opening exposing a portion of the first electrode;
a connection pattern on the connection electrode and the pixel defining layer and electrically connected to the connection electrode;
an electrode layer on the first electrode and electrically connected to the connection pattern;
a separator on the pixel defining layer and the connection pattern, separating the electrode layer into a plurality of second electrodes spaced apart from each other, and covering at least a portion of the connection pattern; and
an additional connection pattern on the pixel defining layer and extending from the connection pattern in a direction away from a central portion of the separator in a cross-section.
